(19) United States
(12) Patent Application Publication
(10) Pub. No.: US 2026/0268848 A1
(43) Pub. Date: Sep. 10, 2026

(54) PIXEL AND ELECTRONIC DEVICE INCLUDING THE SAME

(71) Applicant: Samsung Display Co., Ltd., Yongin-si (KR)

(72) Inventors: WONJUN LEE, Yongin-si (KR); SUNGMIN SON, Yongin-si (KR); Minji KIM, Yongin-si (KR); GEUMJU MOON, Yongin-si (KR)

(21) Appl. No.: 19/425,860

(22) Filed: Dec. 18, 2025

(30) Foreign Application Priority Data
Mar. 6, 2025 (KR) 10-2025-0028744

(51) Int. Cl. G09G 3/3233

(52) U.S. Cl. CPC G09G 3/3233; G09G 2300/0426; G09G 2300/0819; G09G 2300/0842; G09G 2300/0861; G09G 2310/08; G09G 2320/0238; G09G 2320/045; G09G 2330/021

(57) ABSTRACT

An electronic device includes: a display panel including a first display area having a first light transmittance and a second display area having a second light transmittance, the display panel including first pixels in the first display area and second pixels in the second display area; and a processor to drive the display panel, wherein each of the first pixels includes: a first light-emitting element electrically connected between a first power line to provide a first power supply voltage and a second power line to provide a second power supply voltage having a voltage level lower than the first power supply voltage; and a first pixel circuit electrically connected to the first light-emitting element, wherein the first pixel circuit includes: a first transistor including a first electrode connected to a first node, a second electrode connected to a second node, and a gate electrode connected with a third node.

### CROSS-REFERENCE TO RELATED APPLICATION

This application claims priority to and the benefit of Korean Patent Application No. 10-2025-0028744, filed on Mar. 6, 2025, the entire disclosure of which is incorporated by reference herein.

### BACKGROUND

The present disclosure relates to a pixel and an electronic device with improved display quality.

Various types of display devices are used to provide image information, and the display device may include an electronic module that receives an external signal or provides an output signal to the outside. For example, the electronic module may include an infrared sensing sensor, a proximity sensor, a camera module, and/or the like, and there is an increasing demand for a display device capable of obtaining a high-definition photographed image.

In order to increase a region where an image is displayed in the display device, an electronic module such as a camera module is disposed in the region where the image is displayed. The display panel may reduce the number of pixels disposed in a region overlapping with the electronic module to prevent performance degradation of the electronic module.

### SUMMARY

Aspects and features of embodiments of the present disclosure is to provide a pixel and an electronic device with improved display quality.

According to one or more embodiments of the present disclosure, an electronic device includes: a display panel including a first display area having a first light transmittance and a second display area having a second light transmittance lower than the first light transmittance, the display panel including a plurality of first pixels in the first display area and a plurality of second pixels in the second display area; and a processor configured to drive the display panel, wherein each of the plurality of first pixels includes: a first light-emitting element electrically connected between a first power line configured to provide a first power supply voltage and a second power line configured to provide a second power supply voltage having a voltage level lower than the first power supply voltage; and a first pixel circuit electrically connected to the first light-emitting element, wherein the first pixel circuit includes: a first transistor including a first electrode connected to a first node, a second electrode connected to a second node, and a gate electrode connected with a third node; a second transistor including a first electrode connected to a data line configured to provide a data voltage, a second electrode connected to the first node, and a gate electrode configured to receive a first scan signal; a capacitor electrically connected between the third node and the first node; and a third transistor including a first electrode connected to a first voltage line configured to provide a luminance control voltage having a voltage level higher than the second power supply voltage, a second electrode connected to the capacitor, and a gate electrode configured to receive a second scan signal.

According to one or more embodiments, the first pixel circuit further includes a fourth transistor including a first electrode electrically connected to the first power line, a second electrode connected to the first node, and a gate electrode configured to receive a light-emission control signal.

According to one or more embodiments, the second scan signal is out of phase with the light-emission control signal.

According to one or more embodiments, the first pixel circuit further includes: a fifth transistor including a first electrode connected to the second node, a second electrode connected to the third node, and a gate electrode configured to receive a third scan signal; and a sixth transistor including a first electrode connected to a second voltage line configured to provide a first initialization voltage, a second electrode connected to the third node, and a gate electrode configured to receive a fourth scan signal.

According to one or more embodiments, each of the first and second transistors includes a first semiconductor pattern including a first material, and wherein each of the fifth and sixth transistors includes a second semiconductor pattern including a second material different from the first material.

According to one or more embodiments, the first pixel circuit further includes a seventh transistor including a first electrode connected to the first light-emitting element, a second electrode connected to a third voltage line configured to provide a second initialization voltage, and a gate electrode configured to receive a fifth scan signal.

According to one or more embodiments, the fifth scan signal is a signal obtained by shifting the first scan signal by a selected period.

According to one or more embodiments, the first pixel circuit further includes: an eighth transistor including a first electrode connected to the first power line, a second electrode connected to the fourth transistor, and a gate electrode configured to receive the light-emission control signal; and a ninth transistor including a first electrode connected to the second node, a second electrode connected to the first light-emitting element, and a gate electrode configured to receive the light-emission control signal.

According to one or more embodiments, the luminance control voltage has a voltage level that is the same as the first power supply voltage.

According to one or more embodiments, the luminance control voltage has a voltage level that is lower than the first power supply voltage.

According to one or more embodiments, the luminance control voltage has a voltage level that is higher than the first power supply voltage.

According to one or more embodiments, each of the plurality of second pixels includes: a second light-emitting element; and a second pixel circuit electrically connected to the second light-emitting element and is different from the first pixel circuit.

According to one or more embodiments, the second scan signal and the third scan signal are the same.

According to one or more embodiments, the first pixel circuit further includes a tenth transistor including a first electrode connected to the first voltage line, a second electrode connected to the first node, and a gate electrode configured to receive the fifth scan signal.

According to one or more embodiments, a pixel includes: a light-emitting element electrically connected between a first power line configured to provide a first power supply voltage and a second power line configured to provide a second power supply voltage having a voltage level that is lower than the first power supply voltage; and a first pixel circuit electrically connected to the light-emitting element; wherein the first pixel circuit includes: a first transistor including a first electrode connected to a first node, a second electrode connected to a second node, and a gate electrode connected to a third node; a second transistor including a first electrode connected to a data line configured to provide a data voltage, a second electrode connected to the first node, and a gate electrode configured to receive a first scan signal; a capacitor electrically connected between the third node and the first node; and a third transistor including a first electrode connected to a first voltage line configured to provide a luminance control voltage having a voltage level that is higher than the second power supply voltage, a second electrode connected to the capacitor, and a gate electrode configured to receive a second scan signal.

According to one or more embodiments, the first pixel circuit further includes a fourth transistor including a first electrode electrically connected to the first power line, a second electrode connected to the first node, and a gate electrode configured to receive a light-emission control signal.

According to one or more embodiments, the second scan signal is out of phase with the light-emission control signal.

According to one or more embodiments, the first pixel circuit further includes: a fifth transistor including a first electrode connected to the second node, a second electrode connected to the third node, and a gate electrode configured to receive a third scan signal; and a sixth transistor including a first electrode connected to a second voltage line configured to provide a first initialization voltage, a second electrode connected to the third node, and a gate electrode configured to receive a fourth scan signal.

According to one or more embodiments, each of the first and second transistors includes a first semiconductor pattern including a first material, and each of the fifth and sixth transistors includes a second semiconductor pattern including a second material different from the first material.

According to one or more embodiments, the luminance control voltage is defined within a selected range with reference to the first power supply voltage.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles and scope of the present disclosure. In the drawings:

FIG. 1 is a block diagram of an electronic device, according to one or more embodiments of the present disclosure.

FIG. 2 is a schematic diagram of an electronic device in accordance with various embodiments.

FIG. 3 is a perspective view of an electronic device, according to one or more embodiments of the present disclosure.

FIG. 4 is an exploded perspective view of an electronic device, according to one or more embodiments of the present disclosure.

FIG. 5 is a cross-sectional view of the electronic device taken along the line I-I′ shown in FIG. 4, according to one or more embodiments of the present disclosure.

FIG. 6 is a plan view of a display panel, according to one or more embodiments of the present disclosure.

FIG. 7 is a plan view of a first display area, according to one or more embodiments of the present disclosure.

FIG. 8 is a cross-sectional view of the display panel taken along the line II-II′ shown in FIG. 7, according to one or more embodiments of the present disclosure.

FIG. 9 is an equivalent circuit diagram of a first pixel, according to one or more embodiments of the present disclosure.

FIGS. 10A and 10B are timing diagrams for describing an operation of a first pixel, according to one or more embodiments of the present disclosure.

FIG. 11 is a diagram for describing an operation of a first pixel, according to one or more embodiments of the present disclosure.

FIG. 12 is a diagram for describing an operation of a first pixel, according to one or more embodiments of the present disclosure.

FIG. 13 is a diagram for describing an operation of a first pixel, according to one or more embodiments of the present disclosure.

FIG. 14 is a diagram for describing an operation of a first pixel, according to one or more embodiments of the present disclosure.

FIG. 15 is a diagram for describing an operation of a first pixel, according to one or more embodiments of the present disclosure.

FIG. 16 is a diagram for describing an operation of a first pixel, according to one or more embodiments of the present disclosure.

FIG. 17 is a diagram for describing an operation of a first pixel, according to one or more embodiments of the present disclosure.

FIG. 18 is a plan view of a second display area, according to one or more embodiments of the present disclosure.

FIG. 19 is an equivalent circuit diagram of a second pixel, according to one or more embodiments of the present disclosure.

FIG. 20 is a timing diagram for describing an operation of a first pixel, according to one or more embodiments of the present disclosure.

FIG. 21 is an equivalent circuit diagram of a first pixel, according to one or

more embodiments of the present disclosure.

FIG. 22 is an equivalent circuit diagram of a first pixel, according to one or more embodiments of the present disclosure.

FIG. 23 is a timing diagram of a first pixel, according to one or more embodiments of the present disclosure.

FIG. 24 is an equivalent circuit diagram of a first pixel, according to one or more embodiments of the present disclosure.

FIG. 25 is a plan view of a display panel, according to one or more embodiments of the present disclosure.

FIG. 26 is a cross-sectional view of a display panel according to one or more embodiments of the present disclosure.

### DETAILED DESCRIPTION

Herein, when a component (or region, layer, portion, etc.) is referred to as being “on,” “connected to,” “electrically connected to” or “coupled to” another component, it means that it can be directly disposed/connected/coupled to the other component or a third component may be disposed therebetween.

Like numbers refer to like components. In addition, in the drawings, the thicknesses, proportions, and dimensions of the components are exaggerated for effective description of the technical content. “And/or” includes any and all combinations of one or more of the associated elements. In the specification and the claims, the phrase “at least one of” is intended to include the meaning of “at least one selected from the group of” for the purpose of its meaning and interpretation. For example, “at least one of A and B” may be understood to mean “A, B, or A and B.”

Although the terms first, second, etc. may be used to describe various elements, the elements should not be limited by the terms. The terms are only used for the purpose of distinguishing one component, part, region, layer or portion from another component, part, area, layer or portion. For example, a first component, a first part, a first region, a first layer, or a first portion may be termed a second component, a second part, a second region, a second layer, or a second portion, and similarly a second component, second part, second region, second layer, or second portion may also be termed a first component, first part, first region, first layer, or first portion, without departing from the spirit and scope of the present disclosure. The singular forms “a,” “an,” and “the” include plural referents unless the context clearly dictates otherwise.

In addition, terms such as “below”, “beneath”, “above”, “on top”, and/or the like are used to describe the association of the components shown in the drawings. The terms are described in relative terms with reference to the directions indicated in the figures.

It should be understood that terms such as “comprise” and “include” are intended to specify the presence of stated features, numbers, steps, operations, components, parts, or combinations thereof, but do not preclude the presence or addition of one or more other features, numbers, step, operations, components or combinations thereof.

Unless otherwise defined, all terms (including technical and scientific terms) used herein have the same meaning as commonly understood by one of ordinary skill in the art to which the present disclosure belongs. Furthermore, terms, such as those defined in commonly used dictionaries, should be interpreted as having a meaning that is consistent with their meaning in the context of the relevant art and should not be interpreted in a too idealized or overly formal sense unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described with reference to the drawings.

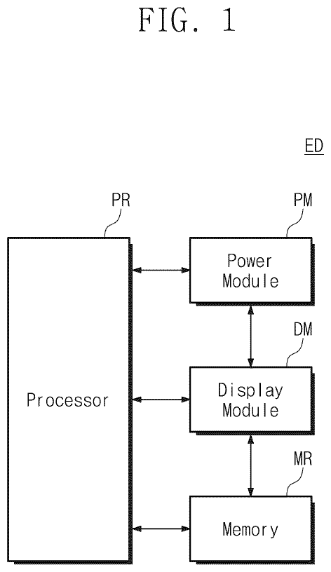

FIG. 1 is a block diagram of an electronic device, according to one or more embodiment of the present disclosure.

The electronic device according to the present disclosure may be provided in various forms. The electronic device according to the present disclosure may further include a module or a device with other additional functions.

Referring to FIG. 1, an electronic device ED according to one or more embodiments may include a display module DM, a processor PR, a memory MR, and a power module PM.

The processor PR may include at least one of a central processing unit (CPU), an application processor (AP), a graphics processing unit (GPU), a communication processor (CP), an image signal processor (ISP), and/or a controller. The processor PR may control the power module PM, the display module DM, and the memory MR.

Data information necessary for the operation of the processor PR or the display module DM may be stored in the memory MR. When the processor PR executes an application stored in the memory MR, an image data voltage and/or an input control signal may be transmitted to the display module DM, and the display module DM may process the received signal to output image information through the display screen.

The power module PM may include a power supply module such as a power adapter or a battery device, and a power conversion module that converts power supplied by the power supply module to generate power required for operation of the electronic device ED.

The display module DM may operate in accordance with an electrical signal. Some of the individual modules that are functionally included in one module may be included in the display module DM, and others may be provided in the electronic device ED separately from the display module DM.

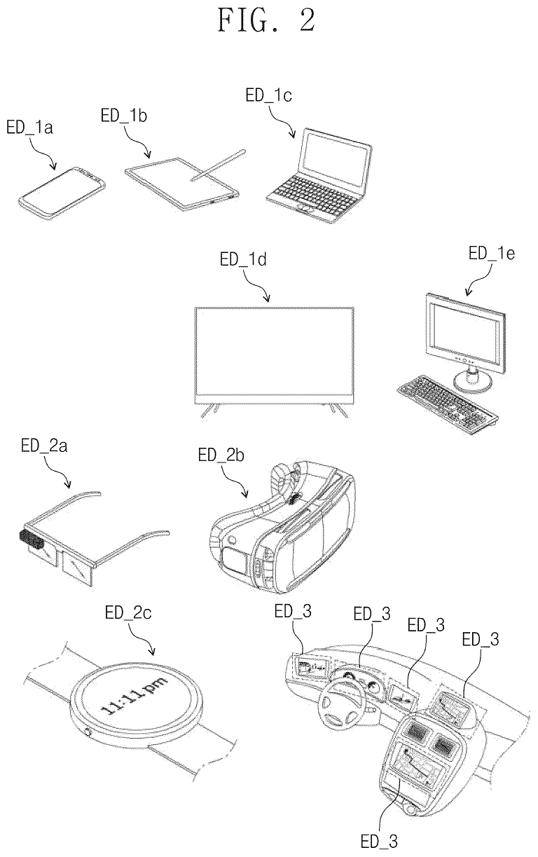

FIG. 2 is a schematic diagram of an electronic device, according to various embodiments.

Referring to FIG. 2, an electronic device according to various embodiments may be an electronic device for image display such as a smartphone ED_1a, a tablet PC ED_1b, a laptop ED_1c, a TV ED_1d, a desk monitor ED_1e, and/or the like, as well as a wearable electronic device including a display module such as smart glasses ED_2a, a head mounted display ED_2b, a smart watch ED_2c, and/or the like.

In addition, the electronic device according to various embodiments may be applied to the inside of a transportation device such as a vehicle to provide various information to a user through an image. For example, the electronic device according to the present disclosure may be provided in a form of an electronic device ED_3 for a vehicle including a display module such as a room mirror display, a CID (Center Information Display) equipped on a dashboard, a center fascia, an instrument panel of a motor vehicle.

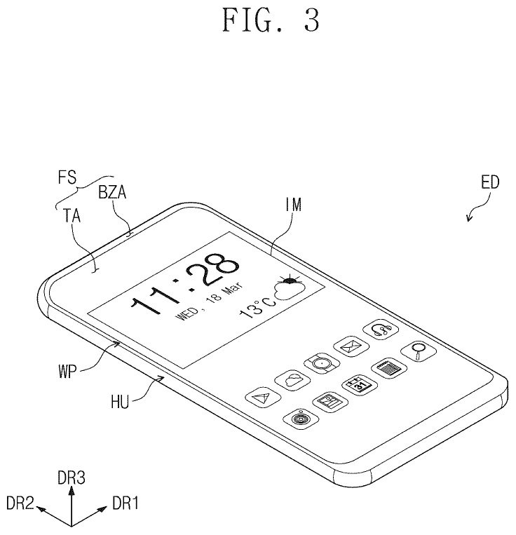

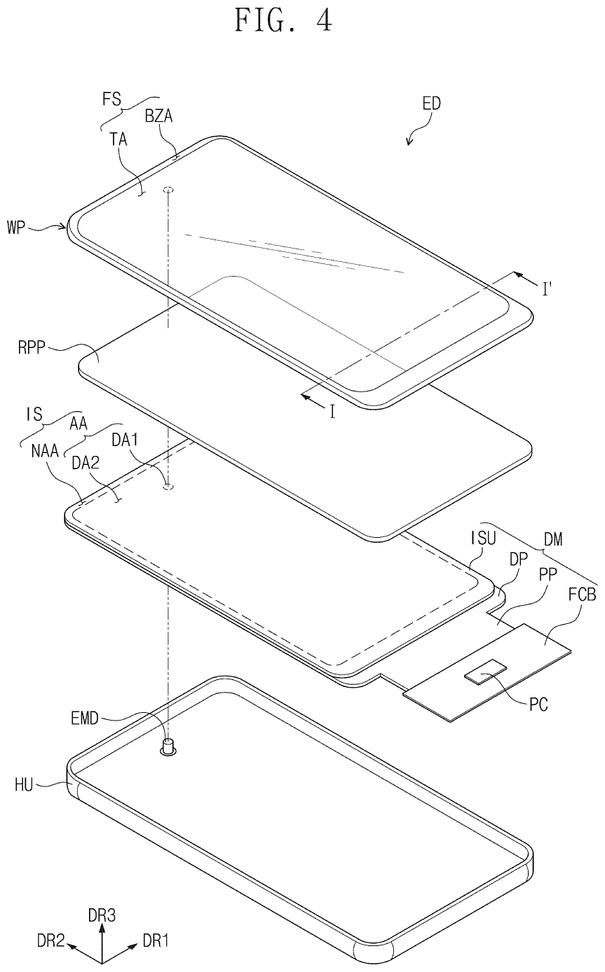

FIG. 3 is a perspective view of an electronic device, according to one or more embodiments of the present disclosure, and FIG. 4 is an exploded perspective view of the electronic device, according to one or more embodiments of the present disclosure.

Referring to FIGS. 3 and 4, the electronic device ED may be a device that is activated in response to an electrical signal. The electronic device ED may include various embodiments. For example, the electronic device ED may be used for a large-sized electronic device such as a television, a monitor, and/or an external billboard, as well as a small or medium-sized electronic device and/or the like such as a personal computer, a notebook computer, a personal digital assistant, an automobile navigation unit, a game machine, a portable electronic device, and/or a camera. Note that these are merely examples, and may be applied to other electronic devices without departing from the concept, spirit, and scope of the present disclosure. In this embodiment, the electronic device ED is shown as a smart phone as an example.

The electronic device ED may display the image IM in a third direction DR3 on a display surface FS parallel to each of a first direction DR1 and a second direction DR2. The image IM may include a still image as well as a dynamic image. A clock and icons are shown as an example of the image IM in FIG. 3. The display surface FS on which the image IM is displayed may correspond to a front surface of the electronic device ED, and may correspond to a front surface of the window panel WP.

In the present embodiment, a front surface (or an upper surface) and a rear surface (or a lower surface) of each of members are defined with reference to the direction in which the image IM is displayed. The front surface and the rear surface may be opposite to each other in the third direction DR3, and a normal direction of each of the front surface and the back surface may be parallel to the third direction DR3. A direction indicated by the first to third directions DR1, DR2, and DR3 may be converted into another direction as a relative concept.

The electronic device ED according to one or more embodiments of the present disclosure may sense a user input applied from an outside. The user's input includes various forms of external inputs, such as a part of the user's body, light, heat, and/or pressure. In addition, the electronic device ED may also sense a user input applied to a side surface or a rear surface of the electronic device ED according to a structure of the electronic device, which is not limited to any one embodiment.

The electronic device ED may include a window panel WP, an anti-reflection panel RPP, a display module DM, an electronic module EMD, and a housing HU. In this embodiment, the window panel WP and the housing HU are combined to form the appearance of the electronic device ED.

The window panel WP may include an optically-transparent insulating material. For example, the window panel WP may include glass and/or plastic. The window panel WP may have a multi-layer structure or a single-layer structure. For example, the window panel WP may include a plurality of plastic films bonded by adhesive, or may include a plastic film and a glass substrate bonded by adhesive.

As described above, the display surface FS of the window panel WP defines the front surface of the electronic device ED. The display surface FS may include a transmissive area TA and a bezel area BZA.

The transmissive area TA may be an optically-transparent area. For example, the transmissive area TA may be a region having a visible light transmittance of about 90% or more. The bezel area BZA may be a region having a relatively low light transmittance compared to the transmissive area TA. The bezel area BZA may have a selected color. The bezel area BZA defines a shape of the transmissive area TA. The bezel area BZA may be adjacent to the transmissive area TA and may be around (e.g., may surround) the transmissive area TA around an edge or a periphery of the transmissive area TA. In the window panel WP according to one or more embodiments of the present disclosure, the bezel area BZA may be omitted.

The anti-reflection panel RPP may be disposed below the window panel WP. The anti-reflection panel RPP reduces a reflectance of external light incident from an upper side of the window panel WP. In one or more embodiments of the present disclosure, the anti-reflection panel RPP may be omitted or embedded in the display module DM.

The display module DM may display the image IM and sense an external input. The display module DM includes a front side IS which includes an active area AA and a peripheral area NAA around an edge or a periphery of the active area AA. The active area AA may be an area activated according to an electrical signal.

In this embodiment, the active area AA is an area where the image IM is displayed and an external input is sensed at the same time. The transmissive area TA overlaps at least the active area AA. For example, the transmissive area TA overlaps a total area or at least a part of the active area AA. Accordingly, the user can view the image IM through the transmissive area TA or provide an external input. However, this is illustratively shown, and a region where the image IM is displayed and a region where an external input is sensed may be separated from each other in the active area AA, which is not limited to any one embodiment.

In the active area AA, a first display area DA1 and a second display area DA2 may be defined. The first display area DA1 may have a first light transmittance. The second display area DA2 may have a second light transmittance lower than the first light transmittance.

The peripheral area NAA may be an area covered by the bezel area BZA. The peripheral area NAA is adjacent to the active area AA. The peripheral area NAA may surround the active area AA. A driver circuit, a driver wiring, and/or the like for driving the active area AA may be disposed in the peripheral area NAA.

In this embodiment, the display module DM is assembled in a flat state in which the active area AA and the peripheral area NAA face the window panel WP. However, this is illustratively shown, and a part of the peripheral area NAA of the display module DM may be bent. Here, a part of the peripheral area NAA faces the rear surface of the electronic device ED, thereby the bezel area BZA in the front surface of the electronic devices ED may be reduced. Alternatively, the display module DM may be assembled in a state where a part of the active area AA is also bent.

The display module DM may include a display panel DP, an input sensor ISU, and a driving circuit.

The display panel DP may be a configuration of substantially generating the image IM. The image IM generated by the display panel DP is visually recognized by the user from the outside through the transmissive area TA.

The input sensor ISU senses an external input applied from the outside. As described above, the input sensor ISU may sense the external input provided to the window panel WP.

The display panel DP may include a pad area PP. A plurality of signal pads may be disposed in the pad area PP of the display panel DP. The display panel DP may be electrically connected to the printed circuit board FCB through signal pads. In one or more embodiments, a driving chip that generates signals necessary for an operation of the display panel DP may be mounted in the pad area PP.

The printed circuit board FCB may include a variety of driving circuits for driving the display panel DP and the input sensor ISU, a connector for power supply, and/or the like. In one or more embodiments, the printed circuit board FCB may include a panel driving circuit PC for driving the display panel DP. The panel driving circuit PC may be formed as an integrated circuit and mounted on the printed circuit board FCB.

The electronics module EMD may be disposed below the display module DM. In one or more embodiments, the electronic module EMD may be coupled to a rear surface of the display module DM via an adhesive member.

The electronic module EMD may be disposed on a plane overlapping the active area AA. Accordingly, a space in which the electronic module EMD is to be disposed may be omitted in the bezel area BZA, and an increase in the area of the bezel area BZA may be prevented.

For example, in the case where the electronic module EMD includes a light source element outputting light, such as an infrared light-emitting diode, an organic light-emitting diode (OLED), a laser diode, a phosphor, and/or the like, the electronic module EMD may output light to the outside through the transmissive area TA. When the electronic module EMD is a light-receiving module such as an infrared detecting sensor, a proximity sensor, a charge-coupled device (CCD), a light detecting sensor, a photo-transistor, or a photodiode, the electronic module EMD may receive external light transmitted through the transmissive area TA. In one or more embodiments, the electronic module EMD may be a camera. The electronic module EMD does not necessarily have to be composed of one element, but may also be composed of a plurality of elements gathered in an array.

The housing HU is coupled with the window panel WP. The housing HU may be coupled to the window panel WP to provide a space in which the anti-reflection panel RPP, the display module DM, and the electronic module EMD are accommodated.

The housing HU may include a material having a relatively high rigidity. For example, the housing HU may include a glass, a plastic, and/or a metal, or may include a plurality of frames and/or plates consisting of a combination thereof. The housing HU may stably protect components of the electronic device ED accommodated in an internal space from external impact.

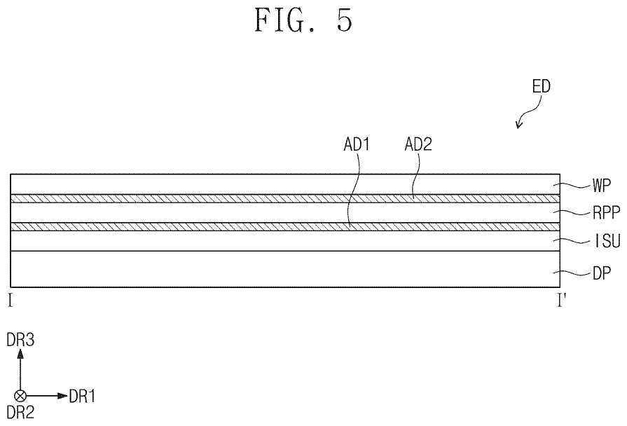

FIG. 5 is a cross-sectional view of the electronic device taken along the line I-I′ shown in FIG. 4, according to one or more embodiments of the present disclosure.

FIG. 5 illustrates a cross section of the display device DD defined by the first direction DR1 and the third direction DR3. In FIG. 5, components of the electronic device ED are shown simply to describe their stack relationship.

Referring to FIG. 5, the electronic device ED may include a display panel DP, an input sensor ISU, an anti-reflector panel RPP, and a window panel WP. At least some components of the display panel DP, the input sensor ISU, the anti-reflection panel RPP, and the window panel WP may be formed by a continuous process, or at least some components may be coupled to each other through an adhesive member. For example, the input sensor ISU and the anti-reflection panel RPP may be coupled by an adhesive member AD1. The anti-reflection panel RPP and the window panel WP may be coupled by an adhesive member AD2.

The adhesive members AD1, AD2 may be a transparent adhesive member such as a Pressure Sensitive Adhesive film (PSA), an Optically Clear Adhesive Film (OCA), and/or an Optically Clear Resin (OCR). The adhesive members described below may include conventional adhesives and/or tackifiers. In one or more embodiments of the present disclosure, the anti-reflection panel RPP and the window panel WP may be replaced or omitted with other components.

In FIG. 5, among the input sensor ISU, the anti-reflector panel RPP, and the window panel WP, the input sensor ISU formed through a continuous process with the display panel DP are directly disposed on the display panel DP. Herein, “the B component is disposed directly on the A component” means that no separate adhesive layer/adhesive member is disposed between the A component and the B component. The B component is formed through a continuous process on a base surface provided by the A component after the A component is formed.

In this embodiment, the anti-reflection panel RPP and the window panel WP are of the “panel” type, and the input sensor ISU is of the “layer” type. The “panel” type includes a base layer that provides a base surface, such as a synthetic resin film, a composite film, a glass substrate, and/or the like, but the “layer” type may omit the base layer. In other words, components of the “layer” type are disposed on a base surface provided by another component. In one or more embodiments of the present disclosure, the anti-reflection panel RPP and the window panel WP may be of the “layer” type.

The display panel DP generates an image, and the input sensor ISU obtains coordinate information of an external input (e.g., a touch event). In one or more embodiments, the display device DD according to one or more embodiments of the present disclosure may further include a protective member disposed on a lower surface (or a rear surface) of the display panel DP. The protective member and the display panel DP may be coupled to each other with an adhesive member.

The display panel DP according to one or more embodiments of the present disclosure may be a light-emitting display panel, but is not limited thereto. For example, the display panel DP may be an organic light-emitting display panel, a quantum dot light-emitting display panel, a micro LED display panel, or a nano LED display panel. The panels are distinguished according to constituent materials of the light-emitting element. The light-emitting layer of the organic light-emitting display panel may include an organic light-emitting material. The light-emitting layer of the quantum dot light-emitting display panel may include a quantum dot and/or a quantum rod, or the like. The light-emitting layer of the micro LED display panel may include a micro LED. The light-emitting layer of the nano LED display panel may include a nano LED.

The anti-reflection panel RPP reduces a reflectance of external light incident from an upper side of the window panel WP. The anti-reflection panel (RPP) according to one or more embodiments of the present disclosure may include a retarder and a polarizer. The retarder may be a film type or a liquid crystal coating type. The polarizer may also be a film type or a liquid crystal coating type. The film type may include a stretched synthetic resin film, and the liquid crystal coating type may include liquid crystals arranged in a selected arrangement. The retarder and the polarizer may further include a protective film. The retarder and the polarizer themselves or the protective film may be defined as the base layer of the anti-reflection panel (RPP).

An anti-reflection panel (RPP) according to one or more embodiments of the present disclosure may include color filters. The color filters have a selected arrangement. The arrangement of color filters may be determined in consideration of emission colors of pixels included in the display panel DP. The anti-reflection panel RPP may further include a black matrix adjacent to the color filters.

An anti-reflection panel (RPP) according to one or more embodiments of the present disclosure may include a destructive interference structure. For example, the destructive interference structure may include a first reflective layer and a second reflective layer respectively disposed on different layers. A first reflected light and a second reflected light respectively reflected by the first reflective layer and the second reflective layer may destructively interfere, thereby reducing an external light reflectance.

The window panel WP according to one or more embodiments of the present disclosure may include a glass substrate and/or a synthetic resin film and/or the like. The window panel WP is not limited to a single layer. The window panel WP may include two or more films bonded with an adhesive member. In one or more embodiments, the window panel WP may also further include a functional coating layer. The functional coating layer may include an anti-fingerprint layer, an anti-reflection layer, a hard coating layer, and/or the like.

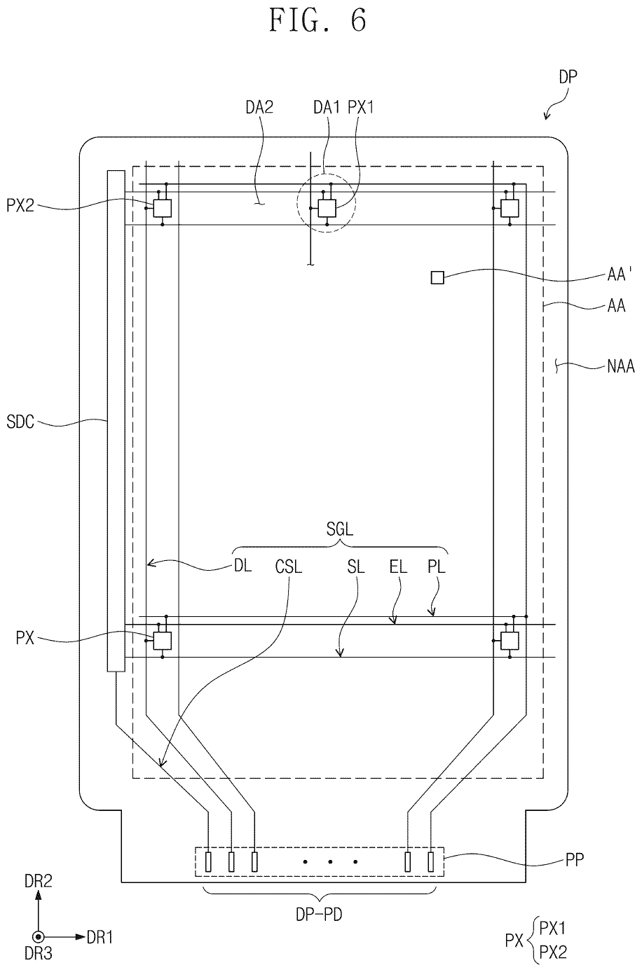

FIG. 6 is a plan view of a display panel, according to one or more embodiments of the present disclosure.

Referring to FIG. 6, the display panel DP may include a scan driving circuit SDC, a plurality of signal lines SGL (hereinafter, signal lines), a plurality of signal pads DP-PD, and a plurality of pixels PX (hereinafter, pixels).

The scan driving circuit SDC generates a plurality of scan signals (hereinafter, scan signals) and sequentially outputs the scan signals to the plurality of scan lines SL (hereinafter, the scan lines) described later. The scan driving circuit SDC may output the scan signals as well as other control signals to the pixels PX.

The scan driving circuit SDC may include a plurality of transistors formed through the same process as transistors in the pixels PX.

The signal lines SGL include scan lines SL, data lines DL, a power line PL, light-emitting control lines EL, and a control signal line CSL. Each of the scan lines SL, the data lines DL, and the light-emission control lines EL is connected to a corresponding one of the pixels PX. The power line PL is commonly connected to the pixels PX. The control signal line CSL may provide control signals to the scan driving circuit SDC. The power line PL may provide a voltage necessary for an operation of the pixels PX. The power line PL may include a plurality of lines that provide different voltages.

The signal pads DP-PD may be electrically connected to the data lines DL, the power line PL, and the control signal line CSL. The signal pads DP-PD are disposed adjacent to each other in a pad area PP defined in a partial area of the peripheral area NAA.

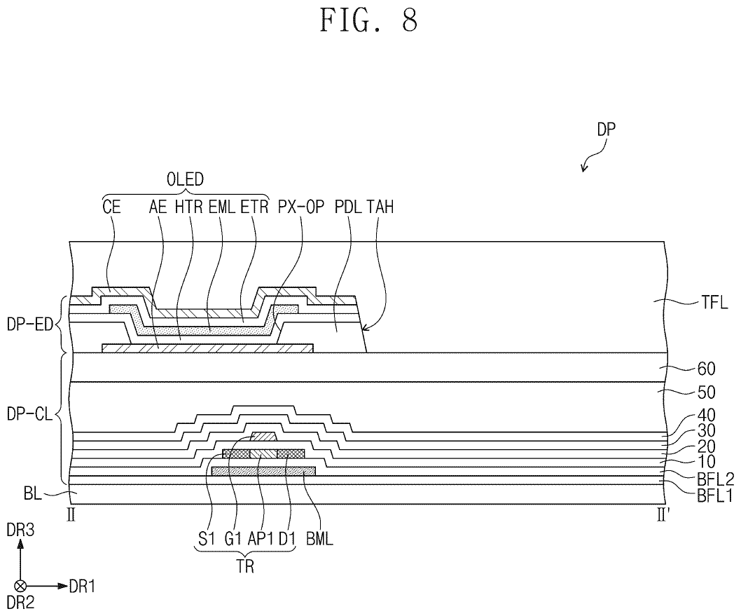

The active area AA may be defined as an area in which the pixels PX are disposed. A plurality of electronic elements may be arranged in the active area AA. The electronic elements include an organic light-emitting diode (OLED) provided in each of the pixels PX and a pixel circuit connected thereto. The scan driving circuit SDC, the signal lines SGL, the signal pads DP-PD, and the pixel circuit may be included in a circuit element layer DP-CL illustrated in FIG. 8.

Each of the pixels PX may include a plurality of transistors, a capacitor, and a light-emitting element. The pixels PX emit light in response to signals received through the scan lines SL, the data lines DL, the light-emission control lines EL, and the power line PL.

The signal pads DP-PD of the display panel DP may be electrically connected to a printed circuit board FCB (see FIG. 4).

A portion of the display panel DP may be bent. A portion of the peripheral area NAA of the display panel DP may be bent with respect to a bending axis parallel to the first direction DR1. The bending axis may be defined to overlap a portion of the data lines DL.

In the active area AA, a first display area DA1 and a second display area DA2 may be defined. A resolution of the first display area DA1 may be different from a resolution of the second display area DA2. For example, the resolution of the second display area DA2 may be higher than the resolution of the first display area DA1.

In one or more embodiments of the present disclosure, the second display area DA2 may be around (e.g., may surround) the first display area DA1. The first display area DA1 may be an area that overlaps with the electronic module EMD (see FIG. 4) on a plane and is adjacent to the second display area DA2. A first light transmittance of the first display area DA1 may be higher than a second light transmittance of the second display area DA2. Thus, transmission/reception of an optical signal to/from the electronic module EMD disposed below the first display area DA1 may be facilitated.

The plurality of pixels PX may include a plurality of first pixels PX1 and a plurality of second pixels PX2. The plurality of first pixels PX1 may be disposed in the first display area DA1. The plurality of second pixels PX2 may be disposed in the second display area DA2.

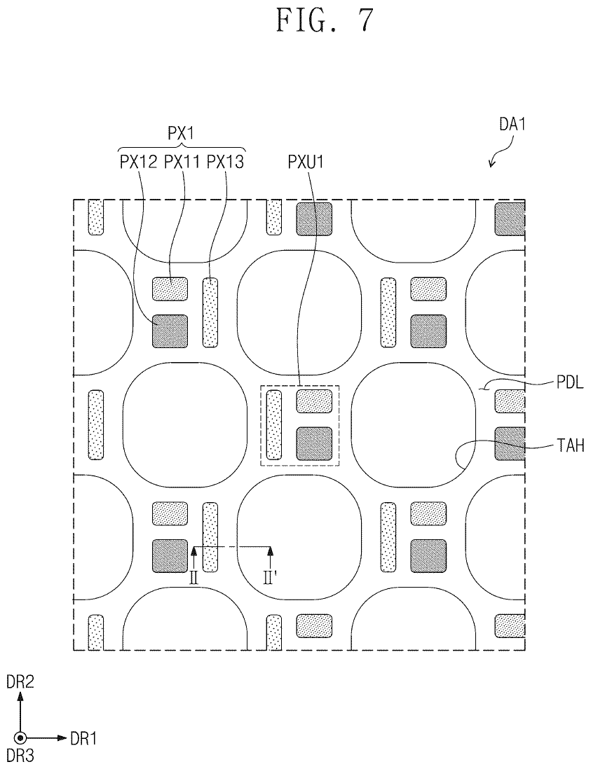

FIG. 7 is a plan view of a first display area, according to one or more embodiments of the present disclosure.

Referring to FIGS. 6 and 7, the display panel DP may include a plurality of first pixels PX1. The first display area DA1 may have higher light transmittance compared to the second display area DA2. A transmissive hole TAH may be defined in the first display area DA1. A plurality of the transmissive holes TAH may be provided in the first display area DA1. The transmissive holes TAH may be defined by a pixel definition film PDL.

A shape of each of the transmissive holes TAH may not be a circle. For example, the shape of each of the transmissive holes TAH is a shape formed by a closed line, but may be a polygon, an amorphous shape including a curve and a straight line, or an amorphous form including curves having different curvatures. The shape of each of the transmissive holes TAH may have various shapes and is not limited to any one embodiment.

The plurality of first pixels PX1 may include a (1-1)-th color pixel PX11, a (1-2)-th color pixel PX12, and a (1-3)-th color pixel PX13. The (1-1)-th color pixel PX11 may be a red light-emitting pixel. The (1-2)-th color pixel PX12 may be a green light-emitting pixel. The (1-3)-th color pixel PX13 may be a blue light-emitting pixel.

A planar shape of each of the (1-1)-th color pixel PX11, the (1-2)-th color pixel PX12, and the (1-3)-th color pixel PX13 may correspond to the shape of the light-emitting region defined in the light-emitting element.

The plurality of first pixels PX1 may define a first pixel unit PXU1. A plurality of the first pixel units PXU1 is provided, and the plurality of first pixel units PXU1 may be arranged along the first direction DR1 and the second direction DR2.

FIG. 8 is a cross-sectional view of the display panel taken along the line II-II′ shown in FIG. 7, according to one or more embodiments of the present disclosure.

Referring to FIG. 8, the display panel DP may include a plurality of insulating layers, a semiconductor pattern, a conductive pattern, a metal pattern, a signal line, and/or the like. The insulating layer, the semiconductor layer, the conductive layer, the metal layer, and/or the like are formed by a method such as coating or vapor deposition. Then, the insulating layer, the semiconductor layer, the conductive layer, and the metal layer may be selectively patterned in a manner of photolithography. In this manner, a semiconductor pattern, a conductive pattern, a shielding pattern, a metal pattern, a signal line, and/or the like included in a circuit element layer DP-CL and the light-emitting element layer DP-ED are formed. After that, an upper insulating layer TFL covering a light-emitting element layer DP-ED may be formed.

A transistor TR and a light-emitting element OLED may be disposed on a base layer BL. The light-emitting element OLED may include a first electrode AE, a second electrode CE, and a light-emitting layer EML disposed between the first electrode AE and the second electrode CE. In addition, the light-emitting element OLED may include a hole-transporting region HTR disposed between the first electrode AE and the light-emitting layer EML and an electron-transporting region ETR disposed between the light-emitting layers EML and the second electrode CE.

A first buffer layer BFL1 may be disposed on the base layer BL. The first buffer layer BFL1 may improve a bonding force between the base layer BL and a metal pattern such as a shielding pattern BML. The first buffer layer BFL1 may include a silicon oxide layer and/or a silicon nitride layer, and the silicon oxide layer and the silicon nitride layers may be stacked by turns (e.g., may be alternatively stacked).

The shielding pattern BML may be disposed on the first buffer layer BFL1. In one or more embodiments, the first buffer layer BFL1 may be omitted, in which case the shielding pattern BML may be provided on the upper surface of the base layer BL.

The shielding pattern BML may overlap with the transistor TR in the third direction DR3. The shielding pattern BML may overlap with an active region AP1 of the transistor TR to serve as a protective layer that prevents electrical characteristics of the active region AP1 from being degraded. In addition, the shielding pattern BML may protect the transistor TR from light and/or moisture introduced from the lower portion of the base layer BL in the manufacturing process of the electronic device. The shielding pattern BML may be formed of a metal material having low light transmittance. For example, the shielding pattern BML may be a metal pattern formed including molybdenum (Mo) and/or the like.

Light incident on the shielding pattern BML may be reflected at a top surface or a bottom surface of the shielding pattern. In one or more embodiments, the second buffer layer BFL2 may be disposed on the shielding pattern BML and the first buffer layer BFL1. The second buffer layer BFL2 may cover the entire shielding pattern BML. A semiconductor pattern is disposed on the second buffer layer BFL2. The semiconductor pattern may include a silicon semiconductor. The semiconductor pattern may include polysilicon and/or amorphous silicon. In addition, the semiconductor pattern may include a metal oxide semiconductor.

The semiconductor pattern has different electrical properties depending on whether they are doped or not. The semiconductor pattern may include doped regions and non-doped regions depending on a degree of doping. The doped region may be doped with an N-type dopant or a P-type dopant. A P-type transistor includes a doped region doped with a P-type dopant.

The doped region may have a larger doping concentration than the undoped region, and the doped region may also have a larger conductivity than the undoped region. The doped region substantially serves as an electrode or a signal line. The undoped region may correspond to an active region (or a channel region) of the transistor TR. In other words, a portion of the semiconductor pattern may be the active region (or a channel region) of the transistor TR, another portion may be the source (or input electrode region) or the drain (output electrode region) of the transistor TR and still another portion may be a connection signal line (or connection electrode). However, the present disclosure is not limited thereto, and the active region (or a channel region) of the transistor TR may also be doped with a dopant.

A source S1, an active pattern AP1, and a drain D1 of the transistor TR are formed from a semiconductor pattern. A first insulating layer 10 may be disposed on the semiconductor pattern and the second buffer layer BFL2. A gate G1 of the transistor TR may be disposed on the first insulating layer 10. A second insulating layer 20 may be disposed on the gate G1 and the first insulating layer 10. A third insulating layer 30, a fourth insulating layer 40, and a fifth insulating layer 50 and/or the like may be disposed on the second insulating layer 20.

In one or more embodiments, the transistor TR and the light-emitting element OLED may be electrically connected to each other by a connection electrode. For example, in one or more embodiments, the connection electrode may electrically connect the transistor TR and the light-emitting element OLED through contact-holes defined in the third insulating layer 30 to the fifth insulating layer 50. A sixth insulating layer 60 may be disposed on the fifth insulating layer 50. Although FIG. 8 illustrates the first to sixth insulating layers 10 to 60 provided in a stacked manner, the number of insulating layers may be reduced or added differently from that illustrated in FIG. 8.

The layers from the first buffer layer BFL1 to the sixth insulating layer 60 may be defined as a circuit element layer DP-CL. The circuit element layer DP-CL may include at least one metal pattern such as the shielding pattern BML, the semiconductor patterns S1, A1, and D1, the gate G1, or a connection electrode.

The first electrode AE may be disposed on the sixth insulating layer 60. The first electrode AE may be an anode electrode. A pixel definition film PDL may be disposed on the first electrode AE and the sixth insulating layer 60. An opening PX_OP for exposing a selected portion of the first electrode AE may be defined in the pixel definition film PDL.

The pixel definition film PDL may be formed of a polymer resin. For example, the pixel definition film PDL may be formed to include a polyacrylate-based resin or a polyimide-based resin. The pixel definition film PDL may be formed to further include an inorganic substance in addition to the polymer resin. The pixel defining film PDL may be formed to include a light absorbing material, or may be formed to include black pigment or black dye. The pixel definition film PDL formed to include a black pigment or a black dye may implement a black pixel definition film. Carbon black and/or the like may be used as a black pigment or a black dye in the formation of the pixel definition film PDL, but the present disclosure is not limited thereto.

The hole-transporting region HTR may be disposed on the first electrode AE and the pixel definition film PDL. The hole-transporting region HTR may include a hole-transporting layer and a hole-injection layer.

The light-emitting layer EML may be disposed on the hole-transporting region HTR. The light-emitting layer EML may be disposed in a region corresponding to the opening PX_OP. The light-emitting layer EML may include organic and/or inorganic materials. In FIG. 8, the light-emitting layer EML may be a portion that emits blue light.

The electron-transporting region ETR may be disposed on the light-emitting layer EML and the hole-transporting region HTR. The electron-transporting region ETR may include an electron-transporting layer and an electron-injection layer.

The second electrode CE may be disposed on the electron-transporting region ETR. The second electrode CE may be a cathode electrode. The second electrode CE may be provided as a common layer.

The layer in which the light-emitting element OLED is disposed may be defined as a light-emitting element layer DP-ED. The upper insulating layer TFL may be disposed on the light-emitting element OLED and the sixth insulating layer 60.

A transmissive hole TAH may be defined by the light-emitting element layer DP-ED. In a portion where the transmissive hole TAH is defined, a light signal provided from outside of the electronic device ED (see FIG. 4) may be transmitted through the display panel DP to be provided to the electronic module EMD (see FIG. 4), or a light signal emitted from the electronic module EMD (see FIG. 4) may be transmitted through the display panel DP to be provide to the outside of the electronic device ED (see FIG. 4). That is, because a metal pattern or a conductive pattern included in the circuit element layer DP-CL and/or the like of the display panel DP is not disposed in the transmissive hole TAH, a light signal provided as transmitted light may be freely transmitted.

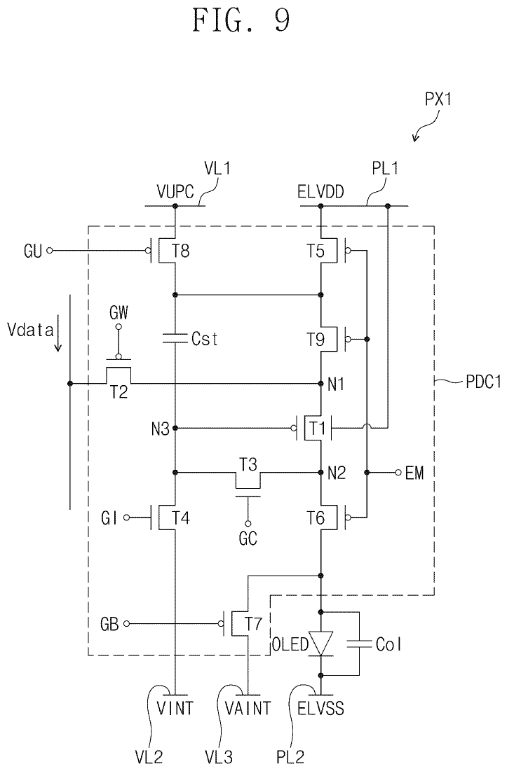

FIG. 9 is an equivalent circuit diagram of a first pixel, according to one or more embodiments of the present disclosure.

Referring to FIGS. 6 and 9, the plurality of scan lines SL may include an initialization scan line outputting an initialization scan signal GI, a compensation scan line outputting a compensation scan signal GC, a write scan line outputting a write scan signal GW, a black scan line outputting a black scan signal GB, and a luminance scan line outputting a luminance scan signal GU.

The light-emission control line EL may output a light-emission control signal EM. The data line DL may output the data voltage Vdata to the first pixel PX1. The data voltage Vdata may have a voltage level corresponding to an image signal input to the electronic device ED (see FIG. 4).

The power line PL may include a first power line PL1, a second power line PL2, a first voltage line VL1, a second voltage line VL2, and a third voltage line VL3.

The first power line PL1 may transfer a first power supply voltage ELVDD to the first pixel PX1. For example, the first power supply voltage ELVDD may have a voltage level of about 4.6 volts (V).

The second power line PL2 may transfer a second power voltage ELVSS having a lower voltage level than the first power voltage ELVDD to the first pixel PX1. For example, the second power supply voltage ELVSS may have a voltage level of about −2.1 V.

The first voltage line VL1 may transfer a luminance control voltage VUPC to the first pixel PX1. The second voltage line VL2 may transfer a first initialization voltage VINT to the first pixel PX1. The third voltage line VL3 may transfer a second initialization voltage VAINT to the first pixel PX1.

The first pixel PX1 may include a light-emitting element OLED and a first pixel circuit PDC1. The light-emitting element OLED may be a light-emitting diode (i.e., LED). As an embodiment of the present disclosure, the light-emitting element OLED may be an organic light emitting diode (OLED) including an organic light emitting layer, but is not particularly limited thereto. The first pixel circuit PDC1 may control an amount of current flowing through the light-emitting element OLED in response to the data voltage Vdata. The light-emitting element OLED may emit light with a selected luminance in response to the amount of current supplied from the first pixel circuit PDC1.

The light emitting element OLED may operate in an on state or an off state. The light-emitting element OLED may include a first electrode AE (see FIG. 8), a light-emitting layer EML (see FIG. 8), and a second electrode CE (see FIG. 8). The first electrode AE (see FIG. 8) may be referred to as an anode. The second electrode (CE, see FIG. 8) may be referred to as a cathode. The first electrode AE (see FIG. 8) and the second electrode CE (see FIG. 9) may act like a kind of light-emitting capacitor Col. The light-emitting capacitor Col may have a selected capacitance. The capacitance may be referred to as a capacitance of a light-emitting device OLED.

The first pixel circuit PDC1 may include a plurality of transistors T1, T2, T3, T4, T5, T6, T7, T8, and T9 and at least one capacitor Cst. A configuration of the first pixel circuit PDC1 according to one or more embodiments of the present disclosure is not limited to the embodiment shown in FIG. 9. The first pixel circuit PDC1 illustrated in FIG. 9 is merely an example, and the configuration of the first pixel circuit PDD1 may be modified and implemented.

The plurality of transistors may include a first transistor T1, a second transistor T2, a third transistor T3, a fourth transistor T4, a fifth transistor T5, a sixth transistor T6, a seventh transistor T7, an eighth transistor T8, and a ninth transistor T9.

Each of the first transistor T1, the second transistor T2, the fifth transistor T5, the sixth transistor T6, the seventh transistor T7, the eighth transistor T8, and the ninth transistor T9 may include a first semiconductor pattern including a first material. For example, each of the first transistor T1, the second transistor T2, the fifth transistor T5, the sixth transistor T6, the seventh transistor T7, the eighth transistor T8, and the ninth transistor T9 may be a P-type transistor whose semiconductor layer is amorphous silicon, low-temperature polycrystalline silicon (LTPS), or crystalline silicon.

Each of the third transistor T3 and the fourth transistor T4 may include a second semiconductor pattern including a second material different from the first material. For example, each of the third transistor T3 and the fourth transistor T4 may be an N-type transistor whose semiconductor layer is an oxide semiconductor.

However, this is illustrative, and all of the plurality of transistors T1, T2, T3, T4, T5, T6, T7, T8, and T9 according to one or more embodiments of the present disclosure may be N-type or P-type transistors, and in another embodiment, at least one of the plurality of the transistors T1, T2, T3, T4, T5, T6, T7, T8, and T9 may be the N-type transistor, and the rest may be the P-type transistor.

The first transistor T1 may be electrically connected between the first power line PL1 and the light-emitting element OLED. The first transistor T1 may include a first electrode connected to a first node N1, a second electrode connected to a second node N2, and a gate electrode connected to a third node N3. The first transistor T1 may further include a lower electrode (or a second gate electrode) corresponding to the gate electrode. The lower electrode may be connected to the first power line PL1. The first transistor T1 may receive the data voltage Vdata transmitted from the data line DL according to the switching operation of the second transistor T2 to supply a driving current to the light-emitting element OLED. The first transistor T1 may be referred to as a driving transistor T1.

The second transistor T2 may be electrically connected between the data line DL and the first electrode of the first transistor T1. The second transistor T2 may include a first electrode connected to the data line DL on which the data voltage Vdata is provided, a second electrode connected to the first node N1, and a gate electrode that receives the write scan signal GW. The second transistor T2 may be turned-on in response to the write scan signal GW transferred through the write scan line to transfer the data voltage Vdata transferred from the data line DL to the first electrode of the first transistor T1. The second transistor T2 may be referred to as a switch transistor T2. The write scan signal GW may be referred to a first scan signal GW.

The third transistor T3 may be connected between the gate electrode and the second electrode of the first transistor T1. The third transistor T3 may include a first electrode connected to the second node N2, a second electrode connected to the third node N3, and a gate electrode that receives the compensation scan signal GC. The third transistor T3 may be turned-on in response to the compensation scan signal GC to connect the gate electrode and the second electrode of the first transistor T1 to each other, thereby diode-connecting the first transistor T1. The compensation scan signal GC may be referred to as a third scan signal GC.

The fourth transistor T4 may be electrically connected between the gate electrode of the first transistor T1 and the second voltage line VL2. The fourth transistor T4 may include a first electrode connected to the second voltage line VL2 provided with the first initialization voltage VINT, a second electrode connected to the third node N3, and a gate electrode that receives the initialization scan signal GI. The fourth transistor T4 may be turned-on in response to the initialization scan signal GI to transfer the first initialization voltage VINT to the third node N3, thereby initializing a potential of the gate electrode of the first transistor T1. The initialization scan signal GI may be referred to as a fourth scan signal GI.

The fifth transistor T5 may be electrically connected between the first power line PL1 and the first node N1. The fifth transistor T5 may include a first electrode connected to the first power line PL1, a second electrode connected to the ninth transistor T9, and a gate electrode that receives the light-emission control signal EM.

The sixth transistor T6 may be electrically connected between the light-emitting element OLED and the first transistor T1. The sixth transistor T6 may include a first electrode connected to the second node N2, a second electrode connected to the light-emitting element OLED, and a gate electrode that receives the light-emission control signal EM.

The seventh transistor T7 may be electrically connected between the third voltage line VL3 and the light-emitting element OLED. The seventh transistor T7 may include a first electrode connected to the light-emitting element OLED, a second electrode connected to the third voltage line VL3 provided with the second initialization voltage VAINT, and a gate electrode that receives the black scan signal GB. The black scan signal GB may be referred to as a fifth scan signal GB.

The eighth transistor T8 may be electrically connected between the first voltage line VL1 and the capacitor Cst. The eighth transistor T8 may include a first electrode connected to the first voltage line VL1 provided with the luminance control voltage VUPC, a second electrode connected to the capacitor Cst, and a gate electrode that receives the luminance scan signal GU. The luminance scan signal GU may be referred to as a second scan signal GU.

The ninth transistor T9 may be electrically connected between the first transistor T1 and the fifth transistor T5. The ninth transistor T9 may include a first electrode electrically connected to the first power line PL1 through the fifth transistor T5, a second electrode connected to the first node N1, and a gate electrode that receives the light-emission control signal EM.

The fifth transistor T5, the sixth transistor T6, and the ninth transistor T9 may be turned-on at the same time in response to the light-emission control signal EM. The first power supply voltage ELVDD applied through the fifth transistor T5 and the ninth transistor T9 that are turned-on may be transferred to the light-emitting element OLED through the sixth transistor T6 via the first transistor T1.

The capacitor Cst may be electrically connected between the third node N3 and the first node N1. For example, the capacitor Cst may be connected between the third node N3 and one electrode of the eighth transistor T8 or the capacitor Cst may be connected between the third node N3 and one electrode of the ninth transistor T9. For example, the capacitor Cst may be electrically connected to the first node N1 via the ninth transistor T9.

The cathode of the light emitting device OLED may be connected to a second power line PL2 providing a second power supply voltage ELVSS.

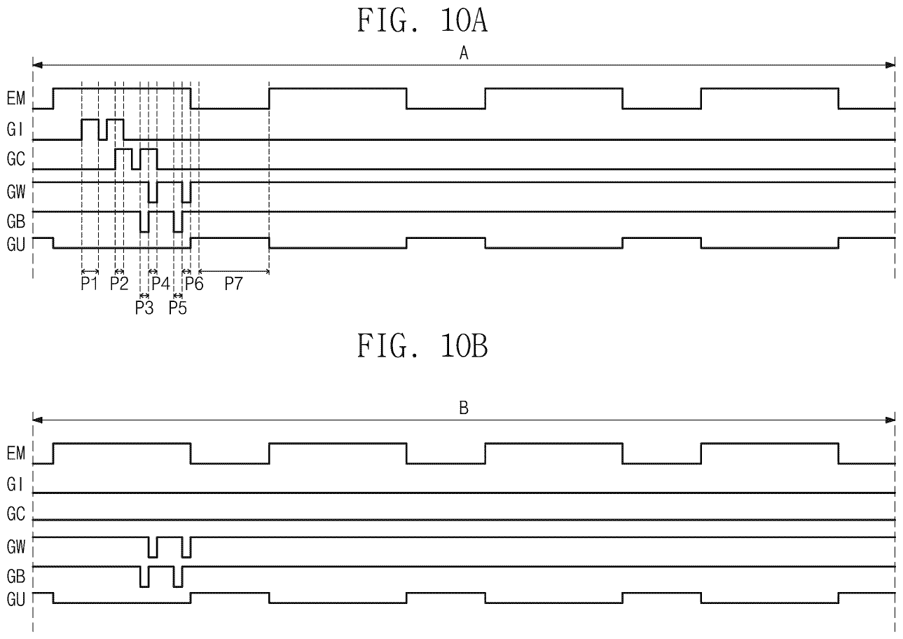

FIGS. 10A and 10B are timing diagrams for describing an operation of a first pixel, according to one or more embodiments of the present disclosure.

Referring to FIGS. 4, 9, 10A, and 10B, the panel driving circuit PC may drive the first pixel PX1 in units of frames. One frame may include a driving section A and/or a scan section B. In the driving section A, the data voltage Vdata of the first transistor T1 may be initialized. By changing a cycle of the driving section A, the initialization and update speed of the data voltage Vdata may be controlled in accordance with the situation, and deteriorations of the first transistor T1 and the light-emitting element OLED may be reduced or prevented. For example, in the case of displaying a still image in which update of the data voltage Vdata does not need to be performed quickly, the first transistor T1 may be driven at a low speed in order to reduce power consumption by reducing a frame cycle.

For example, a length of one frame may increase during low-speed driving. Accordingly, the number of scan section B in which the input data voltage Vdata is maintained may be increased. In the scan section B, the light-emission control signal EM may be maintained in a turned-on status to supply a driving current to the light-emitting element OLED.

The panel driving circuit PC may adjust a driving frequency of the display panel DP through repetition of the scan section B.

The display device DD may synchronize a frame generation of the graphics processing unit included in the display device DD with a frame output timing of the display panel DP. That is, the display panel DP may operate with an adjustable scan rate. For example, if an operating frequency of the display panel DP decreases in a specific operating environment such as still image display, power consumption of the electronic device ED may be reduced.

Each of the driving section A and the scan section B may be a period having a time of 4.2 milliseconds (ms). That is, each of the driving section A and the scan section B may have a frequency of 120 Hz (Hertz). However, this is illustrative, and the time of each of the driving section A and the scan section B according to one or more embodiments of the present disclosure is not limited thereto.

For example, when a graphics processing unit generates a frame having a scan rate of 120 Hz, the scan driving circuit SDC may control to drive only the driving section A once per frame so that the display panel DP operates at a frequency of 120 Hz.

For example, in the case where the graphics processing unit generates a frame having a scan rate of 60 Hz, the scan driving circuit SDC may be driven to have one driving section A and one scan section B per frame.

Each of the light-emission control signal EM and the scan signals GI, GC, GW, GB, and GU may have a high level during some period and a low level during some period. The N-type transistors, which receive the light-emission control signal EM, the scan signals GI, GC, GW, GB, and GU at their respective gate electrodes, are turned-on when the corresponding signal has a high level, and the P-type transistors may be turned-on when the respective signal has a low level.

The driving section A may include a first period P1, a second period P2, a third period P3, a fourth period P4, a fifth period P5, a sixth period P6, and a seventh period P7. The first to sixth periods P1-P6 may be referred to as non-emission periods, and the seventh period P7 may be referred to a light-emission period.

The black scan signal GB may be a signal which the write scan signal GW is shifted by a selected interval. For example, the black scan signal GB may be a write scan signal GW of one preceding line.

The luminance scan signal GU may be out of phase with the light-emission control signal EM.

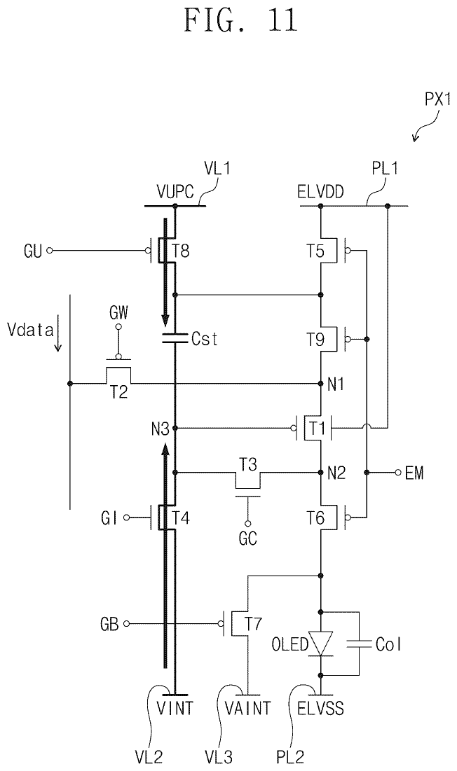

FIG. 11 is a diagram for describing an operation of a first pixel, according to one or more embodiments of the present disclosure. In describing FIG. 11, components described with reference to FIG. 9 are denoted by the same reference numerals, and description thereof is omitted.

Referring to FIGS. 10A and 11, in the first period P1, each of the initialization scan signal GI and the luminance scan signal GU in the first period P1 may be at an active level. The active level of the initialization scan signal GI may be a high level. The active level of the luminance scan signal (GU) may be a low level.

In the first period P1, each of the light-emission control signal EM, the compensation scan signal GC, the write scan signal GW, and the black scan signal GB may be at an inactive level. The inactive level of each of the light-emission control signal EM, the write scan signal GW, and the black scan signal GB may be a high level. The inactive level of the compensation scan signal GC may be a low level.

The fourth transistor T4 may be turned-on in response to the initialization scan signal GI. The first initialization voltage VINT may be provided to the third node N3 through the fourth transistor T4.

During the first period P1, the gate electrode of the first transistor T1 may be initialized to the first initialization voltage VINT. That is, the voltage of the third node N3 may change from the data voltage Vdata of the previous frame period to the first initialization voltage VINT.

The eighth transistor T8 may be turned-on in response to the luminance scan signal GU. A luminance control voltage VUPC may be provided to one electrode of the capacitor Cst through the eighth transistor T8.

The first period P1 may be referred to as a first initialization period.

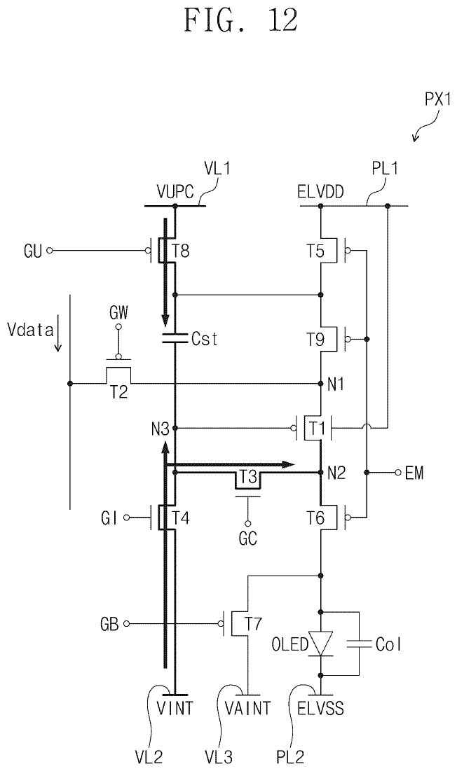

FIG. 12 is a diagram for describing an operation of a first pixel, according to one or more embodiments of the present disclosure. In describing FIG. 12, components described with reference to FIG. 9 are denoted by the same reference numerals, and description thereof is omitted.

Referring to FIGS. 10A and 12, the second period P2 may proceed after the first period P1.

In the second period P2, each of the initialization scan signal GI, the compensation scan signal GC, and the luminance scan signal GU may be at an active level. The active level of the compensation scan signal GC may be a high level. In the second period P2, each of the light-emission control signal EM, the write scan signal GW, and the black scan signal GB may be at an inactive level.

The third transistor T3 may be turned-on in response to the compensation scan signal GC. The first initialization voltage VINT may be provided to the second node N2 through the third transistor T3. During the second period P2, the drain electrode of the first transistor T1 may be initialized to the first initialization voltage VINT.

The fourth transistor T4 may be turned-on in response to the initialization scan signal Gl. The first initialization voltage VINT may be provided to the third node N3 through the fourth transistor T4.

The eighth transistor T8 may be turned-on in response to the luminance scan signal GU. The luminance control voltage VUPC may be provided to one electrode of the capacitor Cst through the eighth transistor T8.

The second period P2 may be referred to as a second initialization period.

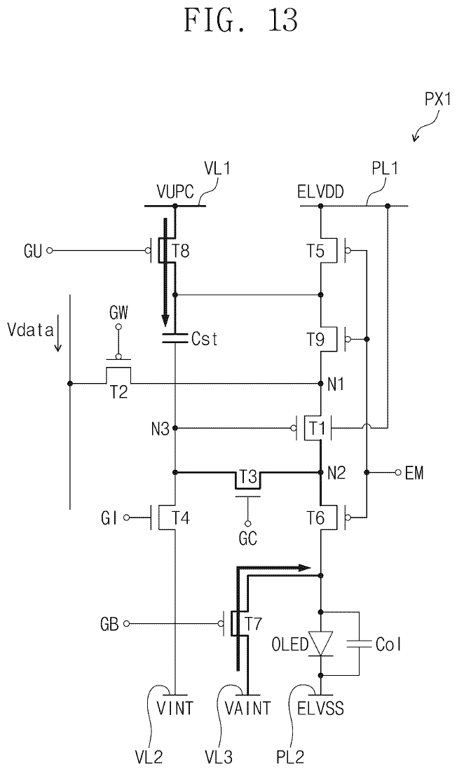

FIG. 13 is a diagram for describing an operation of a first pixel, according to one or more embodiments of the present disclosure. In describing FIG. 13, components described with reference to FIG. 9 are denoted by the same reference numerals, and description thereof is omitted.

Referring to FIGS. 10A and 13, the third period P3 may proceed after the second period P2.

In the third period P3, each of the compensation scan signal GC, the black scan signal GB, and the luminance scan signal GU may be at an active level. The active level of the black scan signal GB may be a low level.

In the third period P3, each of the light-emission control signal EM, the initialization scan signal GI, and the write scan signal GW may be at an inactive level. The inactive level of the initialization scan signal GI may be a low level.

The seventh transistor T7 may be turned-on in response to the black scan signal GB. Through the seventh transistor T7, the anode electrode of the light-emitting device OLED may be initialized to the second initialization voltage VAINT.

According to the present disclosure, the seventh transistor T7 may be turned-on in response to the black scan signal GB to transfer the second initialization voltage VAINT to the light emitting device OLED, thereby initializing the potential of the anode electrode of the light emitting device OLED. When the anode electrode of the light-emitting element OLED is initialized to the second initialization voltage VAINT by the seventh transistor T7, the black characteristics of the first pixel PX1 may be improved. That is, a phenomenon, in which the light-emitting element OLED emits light, due to a current leaking from the first transistor T1 is prevented, therefore the first pixel PX1 may display an accurate black grayscale. Thus, an electronic device (ED, see FIG. 3) with improved display quality may be provided.

The eighth transistor T8 may be turned-on in response to the luminance scan signal GU. The luminance control voltage VUPC may be provided to one electrode of the capacitor Cst through the eighth transistor T8.

The third period P3 may be referred to as a third initialization period.

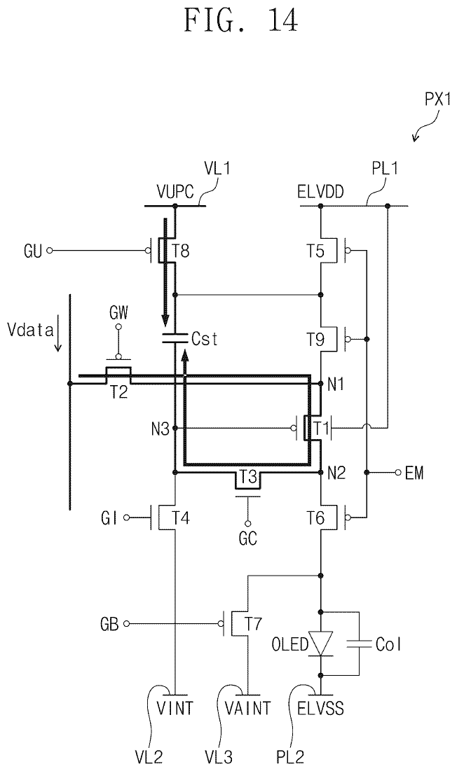

FIG. 14 is a diagram for describing an operation of a first pixel, according to one or more embodiments of the present disclosure. In describing FIG. 14, components described with reference to FIG. 9 are denoted by the same reference numerals, and description thereof is omitted.

Referring to FIGS. 10A and 14, the fourth period P4 may proceed after the third period P3.

In the fourth period P4, each of the compensation scan signal GC, the write scan signal GW, and the luminance scan signal GU may be at an active level. The active level of the write scan signal GW may be a low level.

In the fourth period P4, each of the light-emission control signal EM, the initialization scan signal GI, and the black scan signal GB may be at an inactive level.

The second transistor T2 may be turned-on in response to the write scan signal GW. The data voltage Vdata may be provided to the first node N1 through the second transistor T2.

The third transistor T3 may be turned-on in response to the compensation scan signal GC. The data voltage Vdata provided to the first node N1 through the third transistor T3 may be provided to the third node N3 via the second node N2.

The data voltage Vdata may be provided to the third node N3 via the diode-connected first transistor T1.

The eighth transistor T8 may be turned-on in response to the luminance scan signal GU. The luminance control voltage VUPC may be provided to one electrode of the capacitor Cst through the eighth transistor T8.

The capacitor Cst may store a differential voltage between the third node N3 and the eighth transistor T8. The capacitor Cst may be referred to as a storage capacitor.

The gate electrode of the first transistor T1 may be provided with a voltage obtained by subtracting a value, which is obtained by subtracting the threshold voltage (referred to as Vth) of the first transistor T1 from the data voltage Vdata, from the luminance control voltage VUPC. That is, the gate electrode of the first transistor T1 may be provided with a voltage of VUPC-(Vdata-Vth).

The voltage of the gate electrode of the first transistor T1 may be controlled by a luminance control voltage VUPC.

The luminance control voltage VUPC may be defined within a selected range with reference to the first power supply voltage ELVDD. For example, the luminance control voltage VUPC may be defined between a voltage obtained by subtracting 0.6 V from the first power supply voltage ELVDD and a voltage obtained by adding 0.6 V to the first power supply pressure ELVDD.

The fourth period P4 may be referred to as a writing period.

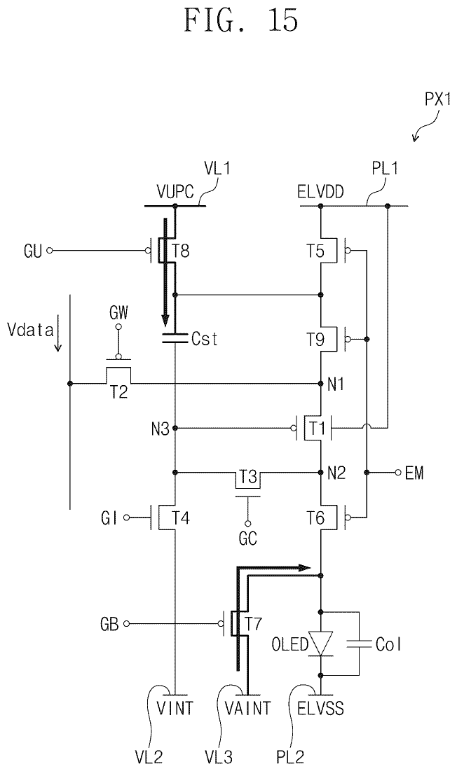

FIG. 15 is a diagram for describing an operation of a first pixel, according to one or more embodiments of the present disclosure. In describing FIG. 15, components described with reference to FIG. 9 are denoted by the same reference numerals, and description thereof is omitted.

Referring to FIGS. 10A and 15, the fifth period P5 may proceed after the fourth period P4.

In the fifth period P5, each of the black scan signal GB and the luminance scan signal GU may be at an active level.

In the fifth period P5, each of the light-emission control signal EM, the initialization scan signal GI, the compensation scan signal GC, and the write scan signal GW may be at an inactive level.

The seventh transistor T7 may be turned-on in response to the black scan signal GB. Through the seventh transistor T7, the anode electrode of the light-emitting device OLED may be initialized to the second initialization voltage VAINT.

The eighth transistor T8 may be turned-on in response to the luminance scan signal GU. The luminance control voltage VUPC may be provided to one electrode of the capacitor Cst through the eighth transistor T8.

The fifth period P5 may be referred to as a fourth initialization period.

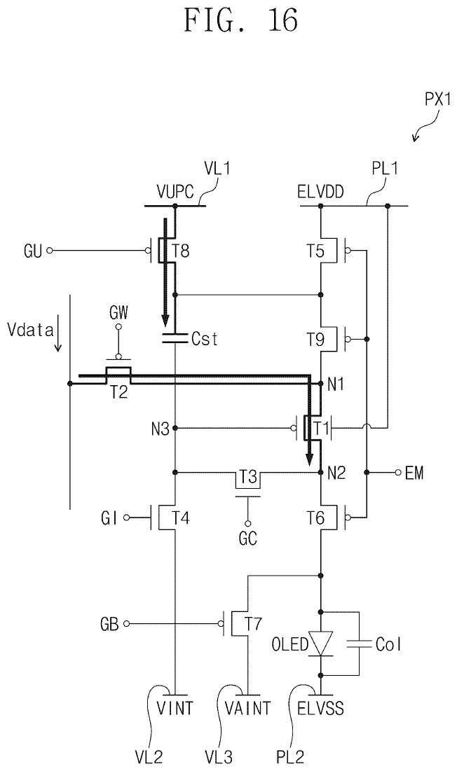

FIG. 16 is a diagram for describing an operation of a first pixel, according to one or more embodiments of the present disclosure. In describing FIG. 16, components described with reference to FIG. 9 are denoted by the same reference numerals, and description thereof is omitted.

Referring to FIGS. 10A and 16, the sixth period P6 may proceed after the fifth period P5.

In the sixth period P6, each of the write scan signal GW and the luminance scan signal GU may be at an active level.

In the sixth period P6, each of the light-emission control signal EM, the initialization scan signal GI, the compensation scan signal GC, and the black scan signal GB may be at an inactive level.

The second transistor T2 may be turned-on in response to the write scan signal GW. The data voltage Vdata may be provided to the first node N1 through the second transistor T2.

By the voltage stored in the capacitor Cst, a voltage of VUPC-(Vdata-Vth) is provided to the gate electrode of the first transistor T1 and the first transistor T1 may be turned-on. The data voltage Vdata may be provided to the second node N2.

The eighth transistor T8 may be turned-on in response to the luminance scan signal GU. The luminance control voltage VUPC may be provided to one electrode of the capacitor Cst through the eighth transistor T8.

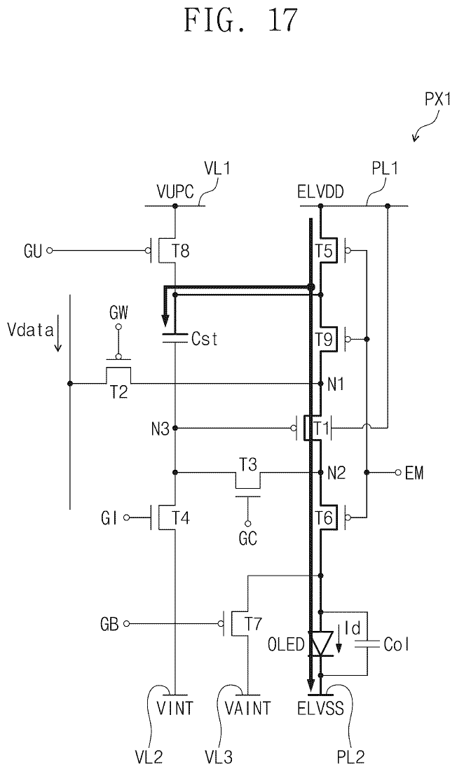

FIG. 17 is a diagram for describing an operation of a first pixel, according to one or more embodiments of the present disclosure. In describing FIG. 17, components described with reference to FIG. 9 are denoted by the same reference numerals, and description thereof is omitted.

Referring to FIGS. 10A and 17, the seventh period P7 may proceed after the sixth period P6.

In the seventh period P7, the light-emission control signal EM may be at an active level.

In the seventh period P7, each of the initialization scan signal GI, the compensation scan signal GC, the write scan signal GW, the black scan signal GB, and the luminance scan signal GU may be at an inactive level.

One electrode of the capacitor Cst may be controlled by the first power supply voltage ELVDD. A gate electrode of the first transistor T1 may be determined based on the luminance control voltage VUPC. The gate electrode of the first transistor T1 may be provided with a voltage of VUPC-ELVDD-(Vdata-Vth).

Each of the fifth transistor T5, the sixth transistor T6, and the ninth transistor T9 may be turned-on in response to the light-emission control signal EM.

By turning-on the fifth transistor T5, the sixth transistor T6, and the ninth transistor T9, a current path may be formed through the first power line PL1, the fifth transistor T5, the ninth transistor T9, the first transistor T1, the sixth transistor T6, the light-emitting element OLED, and the second power line PL2. That is, the driving current Id may flow through the first power line PL1, the fifth transistor T5, the ninth transistor T9, the first transistor T1, the sixth transistor T6, the light-emitting element OLED, and the second power line PL2.

The light-emitting element OLED may emit light based on the driving current Id.

The seventh period P7 may be referred to as a light emission period.

TABLE 1

| VUPC | T1_G | Anode | EL current |
|---|---|---|---|
| 4.0 V(Volt) | 0.41 V | 1.33 V | 47.9 nA |
| 4.6 V | −0.05 V | 1.69 V | 123 nA |
| 5.2 V | −0.51 V | 2.12 V | 261 nA |

In Table 1, “VUPC” may indicate a voltage level of the luminance control voltage VUPC, “T1_G” may indicate a voltage level of a gate electrode of the first transistor T1, “Anode” may indicate a voltage level of an anode electrode of the light-emitting element OLED, and “EL current” may indicate the driving current Id. The luminance control voltage VUPC may have a lower voltage level than the first power supply voltage ELVDD. For example, the luminance control voltage VUPC may be 4.0 V. In this case, the driving current Id flowing through the light-emitting element OLED of the first pixel PX1 may be 47.9 nA (nano Ampere).

The luminance control voltage VUPC may have the same voltage level as the first power supply voltage ELVDD. For example, the luminance control voltage VUPC may be 4.6V. In this case, the driving current Id flowing through the light-emitting element OLED of the first pixel PX1 may be 123 nA. Alternatively, the driving current Id may be 138 nA.

The luminance control voltage VUPC may have a higher voltage level than the first power supply voltage ELVDD. For example, the luminance control voltage VUPC may be 5.2V. In this case, the driving current Id flowing through the light-emitting element OLED of the first pixel PX1 may be 261 nA.

According to the present disclosure, the driving current Id flowing through the light-emitting element OLED of the first pixel PX1 may be proportional to the voltage level of the luminance control voltage VUPC. For example, as the voltage level of the luminance control voltage VUPC increases, the driving current Id may increase. The driving current Id may be controlled in accordance with the voltage level of the luminance control voltage VUPC provided to the first pixel PX1. A luminance of the light-emitting element OLED of the first pixel PX1 may be adjusted (e.g., easily adjusted) using the luminance control voltage VUPC. The first display area DA1 (see FIG. 6), in which the electronic module EMD (see FIG. 4) is disposed, may be driven with high luminance by using the luminance control voltage VUPC. Thus, an electronic device (ED, see FIG. 4) with improved display quality may be provided.

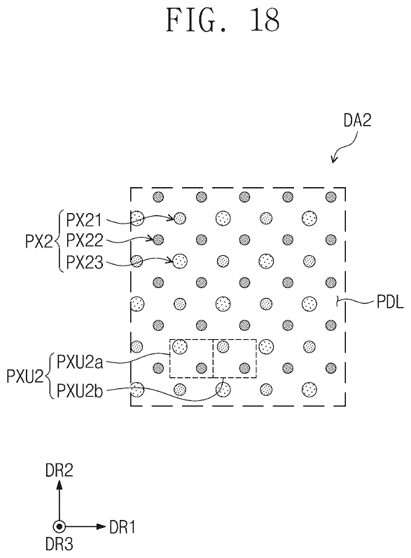

FIG. 18 is a plan view of a second display area, according to one or more embodiments of the present disclosure.

Referring to FIGS. 6 and 18, the display panel DP may include a plurality of second pixels PX2.

The plurality of second pixels PX2 may include a (2-1)-th color pixel PX21, a (2-2)-th color pixel PX22, and a (2-3)-th color pixel PX23. The (2-1)-th color pixel PX21 may be a red light-emitting pixel. The (2-2)-th color pixel PX22 may be a green light-emitting pixel. The (2-3)-th color pixel PX23 may be a blue light emitting pixel.

The plurality of second pixels PX21, PX22, and PX23 may define a second pixel unit PXU2. The second pixel unit PXU2 may include a first sub-pixel unit PXU2a and a second sub-pixel unit PXU2b. The first sub-pixel units PXU2a and the second sub-pixel unit PXU2b may be arranged along the first direction DR1 and the second direction DR2 in turns.

The first sub-pixel unit PXU2a may include the (2-3)-th color pixel PX23 and the (2-2)-th color pixel PX22. The second sub-pixel unit PXU2b may include the (2-1)-th color pixel PX21 and the (2-2)-th color pixel PX22.

The planar shape of each of the plurality of second pixels PX2 may correspond to the shape of the light-emitting region defined in the light-emitting element. The light-emitting region may be a region defined by a pixel definition film (PDL).

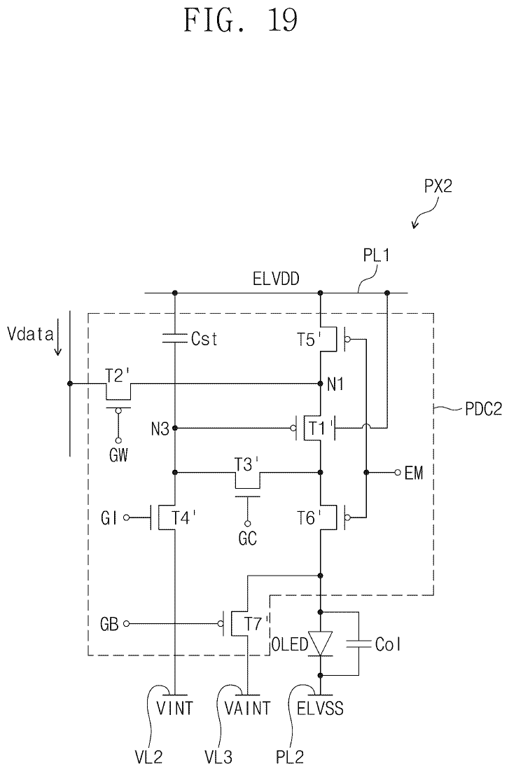

FIG. 19 is an equivalent circuit diagram of a second pixel, according to one or more embodiments of the present disclosure. In describing FIG. 19, components described with reference to FIG. 9 are denoted by the same reference numerals, and description thereof is omitted.

Referring to FIGS. 6 and 19, the second pixel PX2 may include a light-emitting element OLED and a second pixel circuit PDC2. The second pixel circuit PDC2 may be different from the first pixel circuit PDC1 (see FIG. 9).

The second pixel circuit PDC2 may include a plurality of transistors T1′, T2′, T3′, T4′, T5′, T6′, and T7′ and at least one capacitor Cst.

The plurality of transistors T1′, T2′, T3′, T4′, T5′, T6′, and T7′ may include a first transistor T1′, a second transistor T2′, a third transistor T3′, a fourth transistor T4′, a fifth transistor T5′, a sixth transistor T6′, and a seventh transistor T7′.

In the second pixel circuit PDC2, an eighth transistor T8 and a ninth transistor T9 (see FIG. 9) may be excluded and one electrode of the capacitor Cst may be connected to the first power line PL1, as compared to the first pixel circuit PDC1.

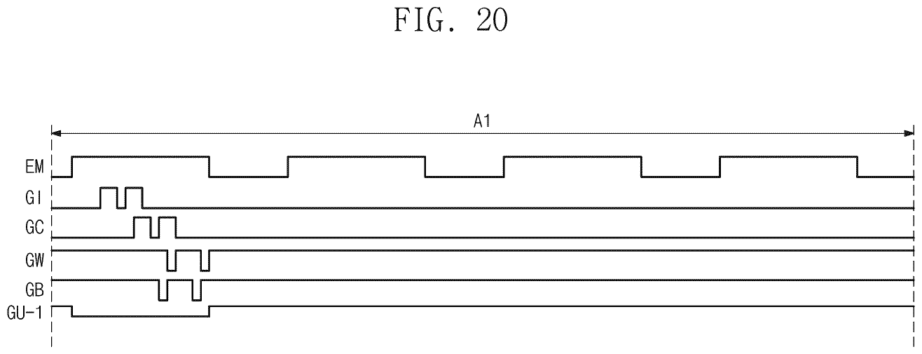

FIG. 20 is a timing diagram for describing an operation of a first pixel, according to one or more embodiments of the present disclosure. In describing FIG. 20, components described with reference to FIG. 10A are denoted by the same reference numerals, and description thereof is omitted.

Referring to FIG. 20, in the driving section A1, the luminance scan signal GU-1 may be out of phase with a portion of the light-emission control signal EM. A remaining portion of the luminance scan signal GU-1 may have a high level.

The luminance scan signal GU-1 may have a low level in a first high level period of the light-emission control signal EM and a high level in the remaining part. However, this is illustrative, and the shape of the luminance scan signal GU-1 according to one or more embodiments of the present disclosure is not limited thereto. For example, the luminance scan signal GU-1 may have a low level in first and third high level periods of the light-emission control signal EM, and a high level in a remaining part.

According to the present disclosure, the number of times of toggling the luminance scan signal GU-1 may be reduced. Thus, an electronic device (ED, see FIG. 3) with reduced power consumption may be provided.

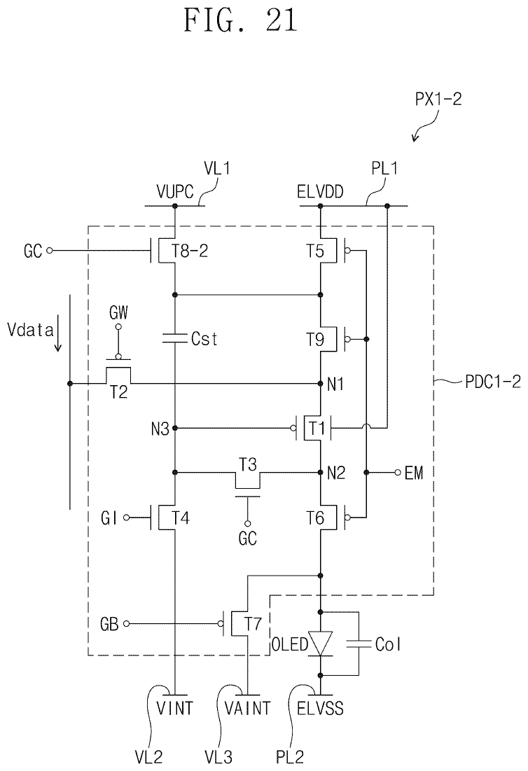

FIG. 21 is an equivalent circuit diagram of a first pixel, according to one or more embodiments of the present disclosure. In describing FIG. 21, components described with reference to FIG. 9 are denoted by the same reference numerals, and description thereof is omitted.

Referring to FIG. 21, the first pixel PX1-2 may include a light-emitting element OLED and a first pixel driving circuit PDC1-2. The first pixel driving circuit PDC1-2 may include an eighth transistor T8-2.

The eighth transistor T8-2 may include a second semiconductor pattern including a second material. For example, the eighth transistor T8-2 may be an N-type transistor whose semiconductor layer is an oxide semiconductor.

The eighth transistor T8-2 may be electrically connected between the first voltage line VL1 and the capacitor Cst. The eighth transistor T8-2 may include a first electrode connected to the first voltage line VL1 on which the luminance control voltage VUPC is provided, a second electrode connected to the capacitor Cst, and a gate electrode that receives the compensation scan signal GC.

The compensation scan signal GC provided to the gate electrode of the eighth transistor T8-2 may be the same as the compensation scan signal GC that is provided to a gate electrode of the third transistor T3.

According to the present disclosure, in the scan driving circuit SDC (see FIG. 6), the circuit for providing the luminance scan signal GU (see FIG. 9) may be omitted. Accordingly, an electronic device ED (see FIG. 3) in which the area of the peripheral area NAA is reduced may be provided.

Further, according to the present disclosure, the eighth transistor T8-2 may operate by sharing the compensation scan signal GC with the third transistor T3 instead of the luminance scan signal GU (see FIG. 9). Thus, an electronic device (ED, see FIG. 3) with reduced power consumption may be provided.

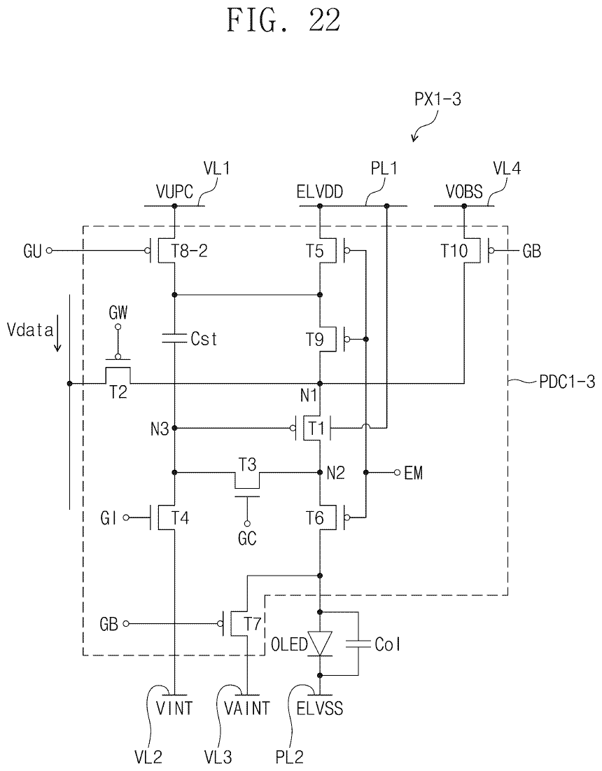

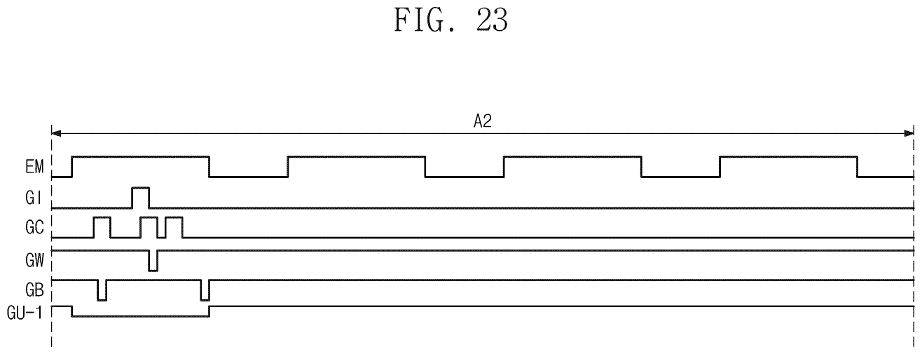

FIG. 22 is an equivalent circuit diagram of a first pixel, according to one or more embodiments of the present disclosure, and FIG. 23 is a timing diagram of the first pixel according to the embodiment of the present disclosure. In describing FIG. 22, components described with reference to FIG. 9 are denoted by the same reference numerals, and description thereof is omitted.

Referring to FIGS. 22 and 23, the first pixel PX1-3 may include a light-emitting element OLED and a first pixel driving circuit PDC1-3. The first pixel driving circuit PDC1-3 may further include a tenth transistor T10.

The power line PL (see FIG. 6) may further include a fourth voltage line VL4.

The fourth voltage line VL4 may transmit the bias voltage VOBS to the first pixel PX1-3.

The tenth transistor T10 may be electrically connected between the fourth voltage line VL4 and the first node N1. The tenth transistor T10 may include a first electrode connected to the fourth voltage line VL4, a second electrode connected to the first node N1, and a gate electrode that receives the black scan signal GB. The tenth transistor T10 may provide the bias voltage VOBS to the first electrode of the first transistor T1 in response to the black scan signal GB. The bias voltage VOBS may be set to a voltage level (e.g., 4V~5V) suitable for compensating for the hysteresis characteristics of the first transistor T1.

However, this is illustrative, and a configuration of the tenth transistor T10 according to one or more embodiments of the present disclosure is not limited thereto. For example, the fourth voltage line VOBS may be omitted, and the first electrode of the tenth transistor T10 may be connected to the first voltage line VL1. The tenth transistor T10 may provide the luminance control voltage VUPC to the first electrode of the first transistor T1 in response to the black scan signal GB.

The first pixel PX1-3 may operate according to the driving section A2.

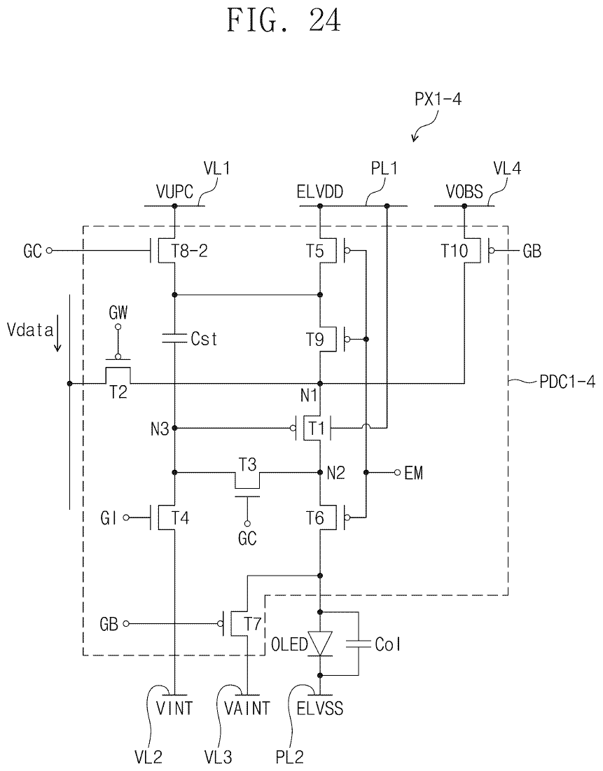

FIG. 24 is an equivalent circuit diagram of a first pixel, according to one or more embodiments of the present disclosure. In describing FIG. 24, components described with reference to FIG. 9 are denoted by the same reference numerals, and description thereof is omitted.

Referring to FIG. 24, the first pixel PX1-4 may include a light-emitting element OLED and a first pixel driving circuit PDC1-4. The first pixel driving circuit PDC1-4 may further include an eighth transistor T8-2 and a tenth transistor T10.

The eighth transistor T8-2 may include a second semiconductor pattern including a second material. For example, the eighth transistor T8-2 may be an N-type transistor whose semiconductor layer is an oxide semiconductor.

The eighth transistor T8-2 may be electrically connected between the first voltage line VL1 and the capacitor Cst. The eighth transistor T8-2 may include a first electrode connected to the first voltage line VL1 on which the luminance control voltage VUPC is provided, a second electrode connected to the capacitor Cst, and a gate electrode that receives the compensation scan signal GC.

The tenth transistor T10 may be electrically connected between the fourth voltage line VL4 and the first node N1. The tenth transistor T10 may include a first electrode connected to the fourth voltage line VL4, a second electrode connected to the first node N1, and a gate electrode that receives the black scan signal GB. The tenth transistor T10 may provide a bias voltage VOBS to the first electrode of the first transistor T1 in response to the black scan signal GB.

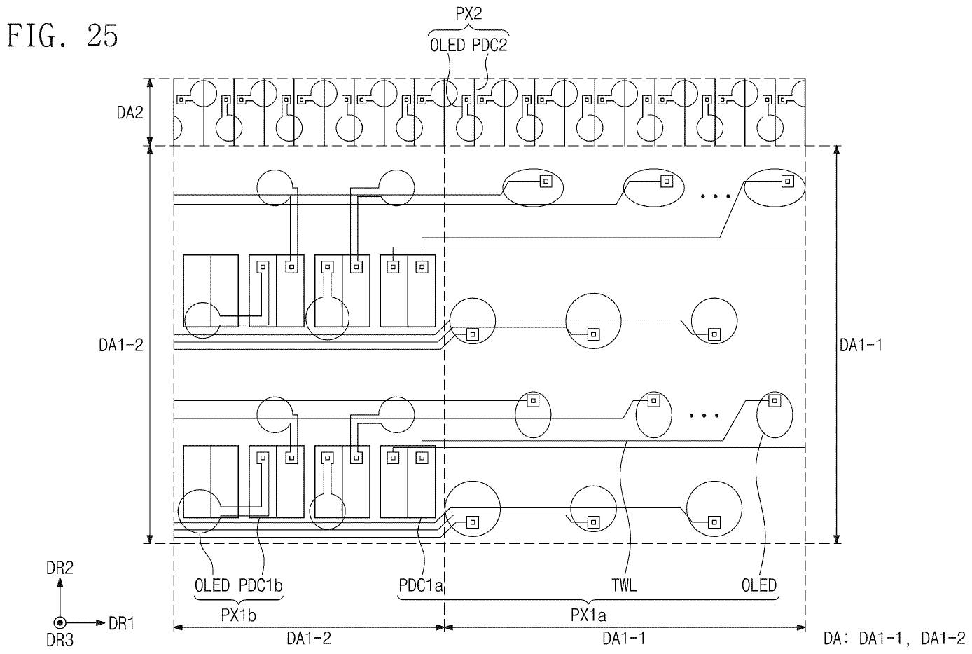

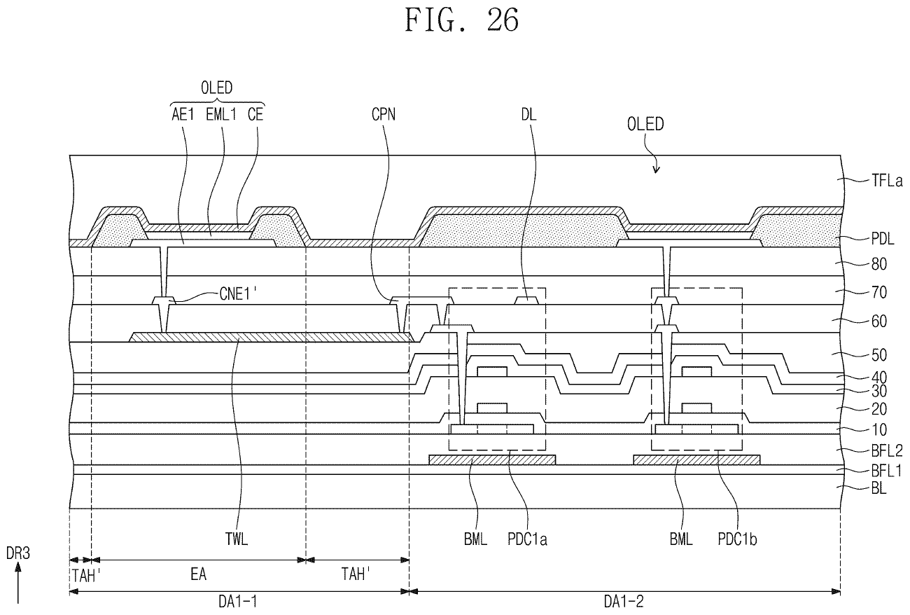

FIG. 25 is a plan view of a display panel, according to one or more embodiments of the present disclosure, and FIG. 26 is a cross-sectional view of the display panel according to one or more embodiments of the present disclosure. In describing FIG. 26, components described with reference to FIG. 8 are denoted by the same reference numerals, and description thereof is omitted.

Referring to FIG. 18, FIG. 25, and FIG. 26, in the first display area DA1, a first sub-area DA1-1 and a second sub-area DA1-2 adjacent to the first sub-area DA2-1 may be defined. The first sub-area DA1-1 may be referred to as a component area, and the first display area DA1 may be referred to a middle area or a transition area.

The plurality of pixels PX may include a second pixel PX2 emitting light in the second display area DA2, a (1-1)-th pixel PX1a emitting light in the first sub-area DA1-1, and a (1-2)-th pixel PX1b emitting light in the second sub-area DA1-2.

Each of the second pixel PX2, the (1-1)-th pixel PX1a, and the (1-2)-th pixel PX1b may be provided in a plurality. In this case, each of the second pixel PX2, the (1-1)-th PX1a, and the (1-2)-th pixel PX1b may include a red pixel, a green pixel, and a blue pixel, and may further include a white pixel, according to one or more embodiments.

The second pixel PX2 may include a light-emitting element (OLED) and a pixel circuit PDC2 for driving the light-emitting element OLED, the (1-1)-th pixel PX1a may include a light-emitting element OLED and a pixel circuit PDC1a for driving the light-emitting device OLED, and the (1-2)-th pixel PX1b may include a light-emitting element OLED and the pixel circuit PDC1b for driving the light-emitting element OLED.

Viewing in a plan view, the (1-1)-th pixel PX1a may overlap the electronic module (EMD, see FIG. 4).

In order to secure an area of a transmissive area, a smaller number of pixels than the second display area DA2 may be provided in the first sub-area DA1-1. A region where a light-emitting element (OLED) is not disposed in the first sub-area DA1-1 may be defined as the transmissive area.

Within a unit area or the same area, the number of the (1-1)-th pixels PX1a arranged in the first sub-region DA1-1 may be smaller than the number of the second pixels PX2 arranged in the second display area DA2.

The pixel circuit PDC1a of the (1-1)-th pixel PX1a may not be disposed in the first sub-area DA1-1. For example, the pixel circuit PDC1a may be disposed in the second sub-area DA1-2 or the peripheral area NAA. In this case, the light transmittance of the first sub-area DA1-1 may increase as compared to the case where the pixel circuit PDC1a is arranged in the first sub-area DA1-1.

The light-emitting element OLED and the pixel circuit PDC1a may be electrically connected to each other through a connection wiring TWL. The connection wiring TWL may overlap with the transmissive area of the first sub-area DA1-1. The connection wiring TWL may include a transparent conductive wire. The transparent conductive wire may include a transparent conductive material or a light transmissive material. For example, the connection wiring TWL may be formed of a transparent conductive oxide (TCO) film of indium tin oxide (ITO), indium zinc oxide (IZO), indium gallium zinc oxide (IGZO), zinc oxide (ZnO), indium oxide (In₂O₃), and/or the like. The second sub-area DA1-2 may be adjacent to the first sub-area DA1-1.

The second sub-area DA1-2 may be around (e.g., may surround) at least a portion of the first sub-area DA1-1. The second sub-area DA1-2 may be a region having a lower light transmittance than the first sub-area DA1-1.

In the second sub-area DA1-2, the pixel circuit PDC1a of the (1-1)-th pixel PX1a, the light-emitting element OLED of the (1-2)-th pixel PX1b, and the pixel circuit PDC1b of the 1-2 pixels PX1b may be arranged. Therefore, the light transmittance of the second sub-area DA1-2 may be lower than that of the first sub-area DA1-1. A resolution of the image displayed in the second sub-area DA1-2 may be lower than a resolution of the image displayed in the second display area DA2.

Layers from a first buffer layer BFL1 to an eighth insulating layer 80 may be disposed over a base layer BL.

A shielding pattern BML may be disposed on the first buffer layer BFL1. The shielding pattern BML may block an electric potential, caused by polarization phenomenon of the base layer BL, from affecting the pixel circuits PDC1a and PDC1b.

A first connection electrode may be disposed on the sixth insulating layer 60. In one or more embodiments, a seventh insulating layer 70 may be disposed over the sixth insulating layer 60. A second connection electrode electrically connected to the first connection electrode may be disposed on the seventh insulating layer 70. A data line DL may be disposed in the seventh insulating layer 70. For example, the data line DL may be disposed over the sixth insulating layer 60 and may be covered by the seventh insulating layer 70. The eighth insulating layer 80 may be disposed over the seventh insulating layer 70.

A layer in which light-emitting elements (OLEDs) are disposed may be disposed over the eighth insulating layer 80.

The light-emitting element OLED may include a first electrode AE1, a light-emitting layer EML1, and a second electrode CE. The second electrode CE may be connected to the pixels PX and provided in common. The first electrode AE1 may be disposed over the eighth insulating layer 80.

The pixel definition film PDL may be disposed over the eighth insulating layer 80. Viewing in a plan view, the pixel definition film PDL disposed in the first sub-region DA1-1 may have an annular shape.

In the first sub-area DA1-1, a region overlapping with a portion, in where the first electrode AE1 and the pixel definition film PDL are disposed, may be defined as an element area EA, and a remaining area may be defined as a transmissive area TAH′.

The first electrode AE1 may be electrically connected to the pixel circuit PDC1a disposed in the second sub-area DA1-2. For example, the first electrode AE1 may be electrically connected to the pixel circuit PDC1a through the connection wiring TWL and a connection bridge CPN. In this case, the connection wire TWL may overlap with the transmissive region TAH′. Thus, the connection wire TWL may include a light transmissive material. The first electrode AE1 may be electrically connected to the connection wire TWL through a connection electrode CNE1′.

The connection wire TWL may be disposed between the fifth insulating layer 50 and the sixth insulating layer 60, but is not particularly limited thereto. The connection bridge CPN may be disposed between the sixth insulating layer 60 and the seventh insulating layer 70. The connection bridge CPN may be connected to the connection wiring TWL and the pixel circuit PDC1a. The upper insulating layer TFLa may be disposed over the second electrode CE.

According to the present disclosure, the driving current flowing through the light-emitting element of the first pixel may be proportional to the voltage level of the luminance control voltage. For example, as the voltage level of the luminance control voltage increases, the drive current may be increased. The driving current may be controlled according to the voltage level of the luminance control voltage provided to the first pixel. The luminance of the light-emitting element of the first pixel may be adjusted (e.g., easily adjusted) using the luminance control voltage. The first display area in which the electronic module is disposed may be driven with high luminance by using the luminance control voltage. Thus, a first pixel with improved display quality and an electronic device including the same may be provided.

While the embodiments of the present disclosure have been described above, it will be understood by those skilled in the art that various modifications and changes may be made to the present disclosure without departing from the spirit and technical scope of the present disclosure as set forth in the following claims.

Therefore, the technical scope of the present disclosure should not be limited to the content described in the detailed description of the specification, but may be determined by the claims and their equivalents.

What is claimed is:

1. An electronic device comprising:
a display panel including a first display area having a first light transmittance and a second display area having a second light transmittance lower than the first light transmittance, the display panel comprising a plurality of first pixels in the first display area and a plurality of second pixels in the second display area; and
a processor configured to drive the display panel,
wherein each of the plurality of first pixels comprises:
a first light-emitting element electrically connected between a first power line configured to provide a first power supply voltage and a second power line configured to provide a second power supply voltage having a voltage level lower than the first power supply voltage; and
a first pixel circuit electrically connected to the first light-emitting element, wherein the first pixel circuit comprises:
a first transistor comprising a first electrode connected to a first node, a second electrode connected to a second node, and a gate electrode connected with a third node;
a second transistor comprising a first electrode connected to a data line configured to provide a data voltage, a second electrode connected to the first node, and a gate electrode configured to receive a first scan signal;
a capacitor electrically connected between the third node and the first node; and
a third transistor comprising a first electrode connected to a first voltage line configured to provide a luminance control voltage having a voltage level higher than the second power supply voltage, a second electrode connected to the capacitor, and a gate electrode configured to receive a second scan signal.

2. The electronic device of claim 1, wherein the first pixel circuit further comprises a fourth transistor comprising a first electrode electrically connected to the first power line, a second electrode connected to the first node, and a gate electrode configured to receive a light-emission control signal.

3. The electronic device of claim 2, wherein the second scan signal is out of phase with the light-emission control signal.

4. The electronic device of claim 2, wherein the first pixel circuit further comprises:
a fifth transistor comprising a first electrode connected to the second node, a second electrode connected to the third node, and a gate electrode configured to receive a third scan signal; and
a sixth transistor comprising a first electrode connected to a second voltage line configured to provide a first initialization voltage, a second electrode connected to the third node, and a gate electrode configured to receive a fourth scan signal.

5. The electronic device of claim 4, wherein each of the first and second transistors comprises a first semiconductor pattern comprising a first material, and
wherein each of the fifth and sixth transistors comprises a second semiconductor pattern comprising a second material different from the first material.

6. The electronic device of claim 4, wherein the first pixel circuit further comprises a seventh transistor comprising a first electrode connected to the first light-emitting element, a second electrode connected to a third voltage line configured to provide a second initialization voltage, and a gate electrode configured to receive a fifth scan signal.

7. The electronic device of claim 6, wherein the fifth scan signal is a signal obtained by shifting the first scan signal by a selected period.

8. The electronic device of claim 2, wherein the first pixel circuit further comprises:
an eighth transistor comprising a first electrode connected to the first power line, a second electrode connected to the fourth transistor, and a gate electrode configured to receive the light-emission control signal; and
a ninth transistor comprising a first electrode connected to the second node, a second electrode connected to the first light-emitting element, and a gate electrode configured to receive the light-emission control signal.

9. The electronic device of claim 1, wherein the luminance control voltage has a voltage level that is the same as the first power supply voltage.

10. The electronic device of claim 1, wherein the luminance control voltage has a voltage level that is lower than the first power supply voltage.

11. The electronic device of claim 1, wherein the luminance control voltage has a voltage level that is higher than the first power supply voltage.

12. The electronic device of claim 1, wherein each of the plurality of second pixels comprises:
a second light-emitting element; and
a second pixel circuit electrically connected to the second light-emitting element and is different from the first pixel circuit.

13. The electronic device of claim 4, wherein the second scan signal and the third scan signal are the same.

14. The electronic device of claim 6, wherein the first pixel circuit further comprises a tenth transistor comprising a first electrode connected to a fourth voltage line configured to provide a bias voltage, a second electrode connected to the first node, and a gate electrode configured to receive the fifth scan signal.

15. A pixel comprising:
a light-emitting element electrically connected between a first power line configured to provide a first power supply voltage and a second power line configured to provide a second power supply voltage having a voltage level that is lower than the first power supply voltage; and
a first pixel circuit electrically connected to the light-emitting element;
wherein the first pixel circuit comprises:
a first transistor comprising a first electrode connected to a first node, a second electrode connected to a second node, and a gate electrode connected to a third node;
a second transistor comprising a first electrode connected to a data line configured to provide a data voltage, a second electrode connected to the first node, and a gate electrode configured to receive a first scan signal;
a capacitor electrically connected between the third node and the first node; and
a third transistor comprising a first electrode connected to a first voltage line configured to provide a luminance control voltage having a voltage level that is higher than the second power supply voltage, a second electrode connected to the capacitor, and a gate electrode configured to receive a second scan signal.

16. The pixel of claim 15, wherein the first pixel circuit further comprises a fourth transistor comprising a first electrode electrically connected to the first power line, a second electrode connected to the first node, and a gate electrode configured to receive a light-emission control signal.

17. The pixel of claim 16, wherein the second scan signal is out of phase with the light-emission control signal.

18. The pixel of claim 16, wherein the first pixel circuit further comprises:
a fifth transistor comprising a first electrode connected to the second node, a second electrode connected to the third node, and a gate electrode configured to receive a third scan signal; and
a sixth transistor comprising a first electrode connected to a second voltage line configured to provide a first initialization voltage, a second electrode connected to the third node, and a gate electrode configured to receive a fourth scan signal.

19. The pixel of claim 18, wherein each of the first and second transistors comprises a first semiconductor pattern comprising a first material, and each of the fifth and sixth transistors comprises a second semiconductor pattern comprising a second material different from the first material.

20. The pixel of claim 15, wherein the luminance control voltage is defined within a selected range with reference to the first power supply voltage.
